(19) United States
(12) Patent Application Publication
(10) Pub. No.: US 2026/0047112 A1
(43) Pub. Date: Feb. 12, 2026

(54) SEMICONDUCTOR DEVICE AND METHOD OF MANUFACTURING THE SAME

(71) Applicant: Renesas Electronics Corporation, Tokyo (JP)

(72) Inventors: Yasutaka NAKASHIBA, Tokyo (JP); Takayuki IGARASHI, Tokyo (JP); Yosuke WATANABE, Tokyo (JP)

(21) Appl. No.: 19/256,844

(22) Filed: Jul. 1, 2025

(30) Foreign Application Priority Data
Aug. 7, 2024 (JP) 2024-131267

(51) Int. Cl. H10D 1/20; H01L 21/78; H10D 1/00

(52) U.S. Cl. CPC H10D 1/20; H01L 21/78; H10D 1/01

(57) ABSTRACT

A semiconductor device includes a semiconductor substrate including a p-type semiconductor and an n-type semiconductor region arranged on the p-type semiconductor region; a first pattern overlapping the n-type semiconductor region in plan view and formed over the semiconductor substrate; and a second pattern overlapping the first pattern in plan view and magnetically or capacitively coupled to the first pattern.

### CROSS-REFERENCE TO RELATED APPLICATION

The disclosure of Japanese Patent Application No. 2024-131267 filed on Aug. 7, 2024, including the specification, drawings and abstract is incorporated herein by reference in its entirety.

### BACKGROUND

The present invention relates to a semiconductor device and a method of manufacturing the same, and relates to a technique effectively applied to, for example, a semiconductor device that enables signal transmission between different potentials by using a pair of inductors inductively coupled to each other and to a method of manufacturing the same.

There is disclosed technique listed below.
[Patent Document 1] International Patent Publication No. WO 2014/097425

The Patent Document 1 describes a technique of suppressing dielectric breakdown in a digital isolator.

### SUMMARY

For example, there is a transformer that enables electrically contactless signal transmission using a pair of inductors inductively coupled to each other. The transformer enables signal transmission in an electrically contactless state, thereby suppressing adverse effect of electrical noise of one circuit on the other circuit. In the transformer configured as described above, reduction in crosstalk noise is further desired.

The number of transformers to be mounted on a semiconductor chip differs depending on an application to a product. However, cutting out/extraction of a semiconductor chip including a predetermined number of transformers from one semiconductor wafer provides excess chips, and leads to decrease in production efficiency.

The above-described problem may also similarly occur in a case using capacitively-coupled capacitors instead of the above-described transformer in the signal transmission in the electrically contactless state.

Other problems and novel characteristics will be apparent from the description of this specification and the accompanying drawings.

An outline of typical aspect of the embodiments disclosed in the present application will be briefly described below.

A semiconductor device according to one embodiment includes: a semiconductor substrate including a first semiconductor region of a first conductivity type and a second semiconductor region of a second conductivity type different from the first conductivity type, arranged on the first semiconductor region, a first pattern overlapping the second semiconductor region in plan view and formed over the semiconductor substrate; and a second pattern overlapping the first pattern in plan view and magnetically or capacitively coupled to the first pattern.

A method of manufacturing a semiconductor device according to one embodiment includes: a step of preparing a lot including a first semiconductor wafer and a second semiconductor wafer; a step of forming a plurality of patterns arranged in a matrix form in plan view over each of the first semiconductor wafer and the second semiconductor wafer; a step of cutting the first semiconductor wafer to obtain a first semiconductor chip having “n” patterns; and a step of cutting the second semiconductor wafer to obtain a second semiconductor chip having “m” patterns. Each of the plurality of patterns includes an upper pattern and a lower pattern that overlap each other in plan view and are magnetically or capacitively coupled to each other, and a conductor pattern surrounding the upper pattern and the lower pattern in plan view.

A method of manufacturing a semiconductor device according to one embodiment includes: a step of forming a plurality of patterns arranged in a matrix form in plan view over a semiconductor wafer; and a step of cutting the semiconductor wafer along a main surface of the semiconductor wafer to obtain a first semiconductor chip having “n” patterns and a second semiconductor chip having “m” patterns. Each of the plurality of patterns includes an upper pattern and a lower pattern that overlap each other in plan view and are magnetically or capacitively coupled to each other, and a conductor pattern surrounding the upper pattern and the lower pattern in plan view.

According to one embodiment disclosed in the present application, the performance of the semiconductor device can be improved.

According to one embodiment disclosed in the present application, the production efficiency of the semiconductor device can be improved.

### BRIEF DESCRIPTIONS OF THE DRAWINGS

FIG. 1 is a diagram illustrating a configuration example of a driving controller that drives a load circuit.

FIG. 2 is an explanatory diagram illustrating a signal transmission example.

FIG. 3 is a diagram illustrating a three-chip configuration including a semiconductor device according to a first embodiment.

FIG. 4 is a diagram illustrating the three-chip configuration including the semiconductor device according to the first embodiment.

FIG. 5 is a diagram illustrating the three-chip configuration including the semiconductor device according to the first embodiment.

FIG. 6 is a planar layout illustrating a semiconductor chip according to the first embodiment.

FIG. 7 is a cross-sectional view of the semiconductor chip taken along a line A-A illustrated in FIG. 6.

FIG. 8 is a plan view in a step of manufacturing the semiconductor device according to the first embodiment.

FIG. 9 is a cross-sectional view in the step of manufacturing the semiconductor device according to the first embodiment.

FIG. 10 is a cross-sectional view in a step of manufacturing the semiconductor device, continued from the step illustrated in FIG. 9.

FIG. 11 is a cross-sectional view in a step of manufacturing the semiconductor device, continued from the step illustrated in FIG. 10.

FIG. 12 is a cross-sectional view in a step of manufacturing the semiconductor device, continued from the step illustrated in FIG. 11.

FIG. 13 is a cross-sectional view in a step of manufacturing the semiconductor device, continued from the step illustrated in FIG. 12.

FIG. 14 is a cross-sectional view in a step of manufacturing the semiconductor device, continued from the step illustrated in FIG. 13.

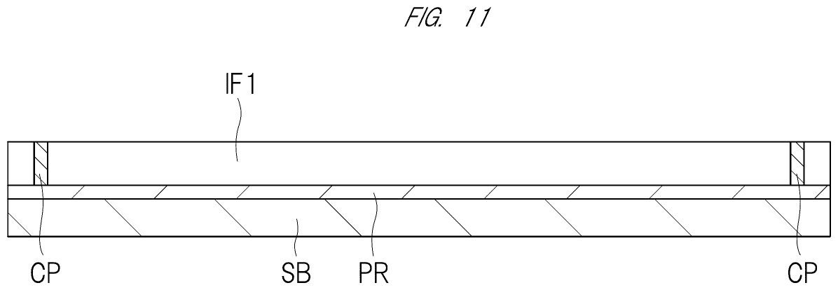

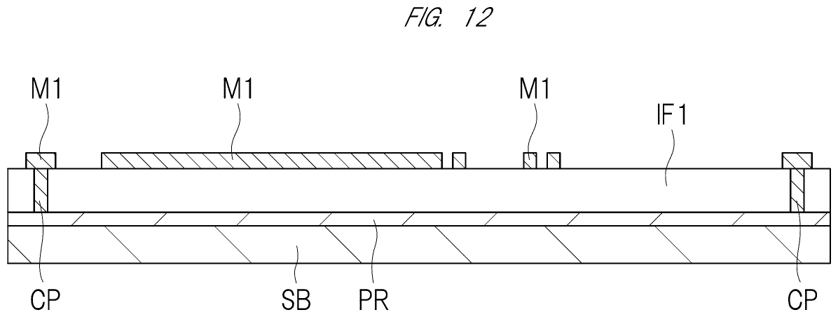

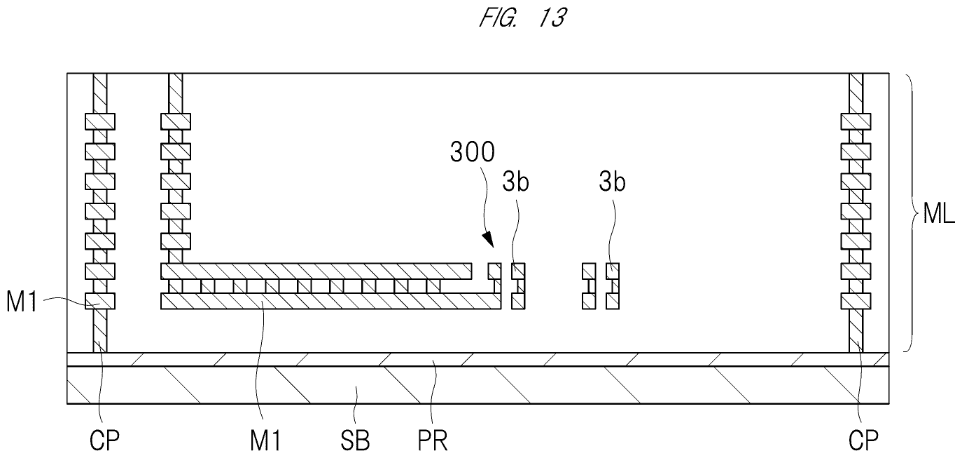

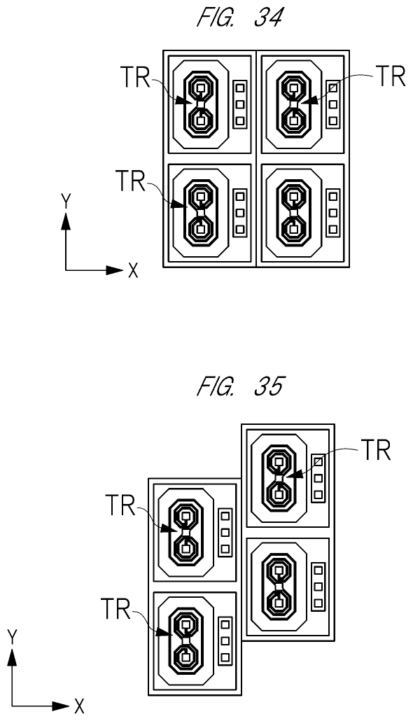

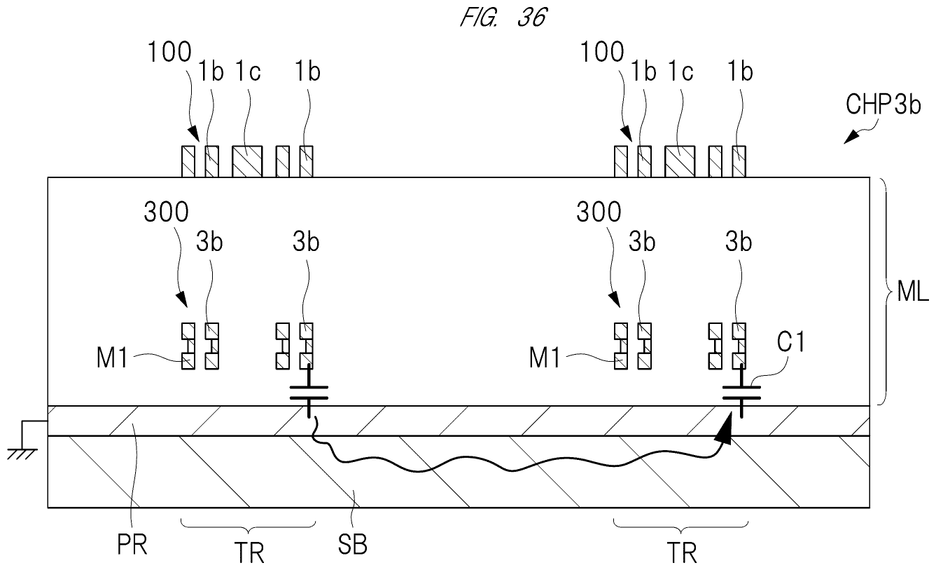

FIG. 5 is a cross-sectional view in a step of manufacturing the semiconductor device, continued from the step illustrated in FIG. 14.

FIG. 16 is a plan view in the step of manufacturing the semiconductor device, continued from the step illustrated in FIG. 14.

FIG. 17 is a plan view in a step of manufacturing the semiconductor device, continued from the step illustrated in FIG. 16.

FIG. 18 is a schematic view illustrating a semiconductor package using the semiconductor device according to the first embodiment.

FIG. 19 is a perspective view illustrating a lot including a plurality of semiconductor wafers according to a modification example of the first embodiment.

FIG. 20 is a plan view in a step of manufacturing a semiconductor device according to the modification example of the first embodiment.

FIG. 21 is a planar layout illustrating a semiconductor chip according to a second embodiment.

FIG. 22 is a cross-sectional view of the semiconductor chip taken along a line B-B illustrated in FIG. 21.

FIG. 23 is a plan view in a step of manufacturing a semiconductor device according to the second embodiment.

FIG. 24 is a cross-sectional view in a step of manufacturing a semiconductor device according to a modification example of the second embodiment.

FIG. 25 is a cross-sectional view in a step of manufacturing the semiconductor device, continued from the step illustrated in FIG. 24.

FIG. 26 is a cross-sectional view in a step of manufacturing the semiconductor device according to the modification example of the second embodiment.

FIG. 27 is a cross-sectional view in a step of manufacturing the semiconductor device according to the modification example of the second embodiment.

FIG. 28 is a cross-sectional view illustrating a semiconductor device according to a third embodiment.

FIG. 29 is a cross-sectional view illustrating a semiconductor device according to a modification example of the third embodiment.

FIG. 30 is a planar layout illustrating a semiconductor device according to a fourth embodiment.

FIG. 31 is a cross-sectional view of a semiconductor chip taken along a line C-C illustrated in FIG. 30.

FIG. 32 is a cross-sectional view in a step of manufacturing the semiconductor device according to the fourth embodiment.

FIG. 33 is a plan view in the step of manufacturing the semiconductor device according to the fourth embodiment;

FIG. 34 is a planar layout illustrating a semiconductor device according to a first comparative example.

FIG. 35 is a planar layout illustrating a semiconductor device according to a second comparative example.

FIG. 36 is a cross-sectional view illustrating a semiconductor device according to a third comparative example.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments will be described in detail with reference to the accompanying drawings. Note that components having the same function are denoted with the same reference symbols throughout all the drawings for describing the embodiments, and the repetitive description thereof will be In addition, the description of the same or similar omitted. portions is not repeated in principle unless otherwise particularly required in the following embodiments.

### First Embodiment

### Circuit Configuration

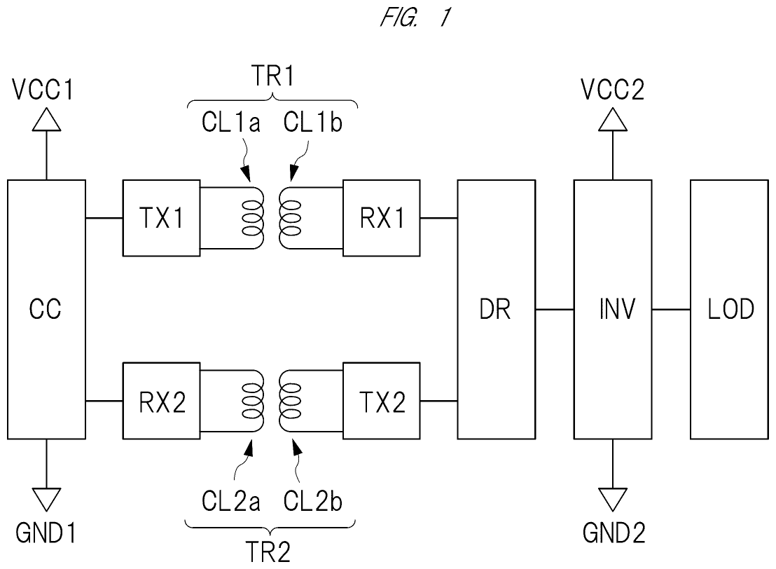

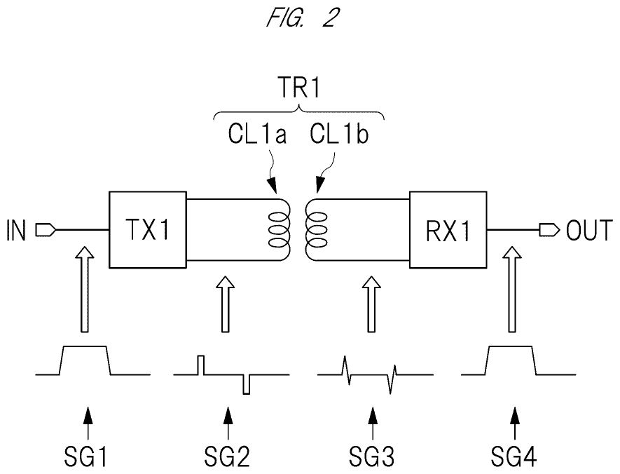

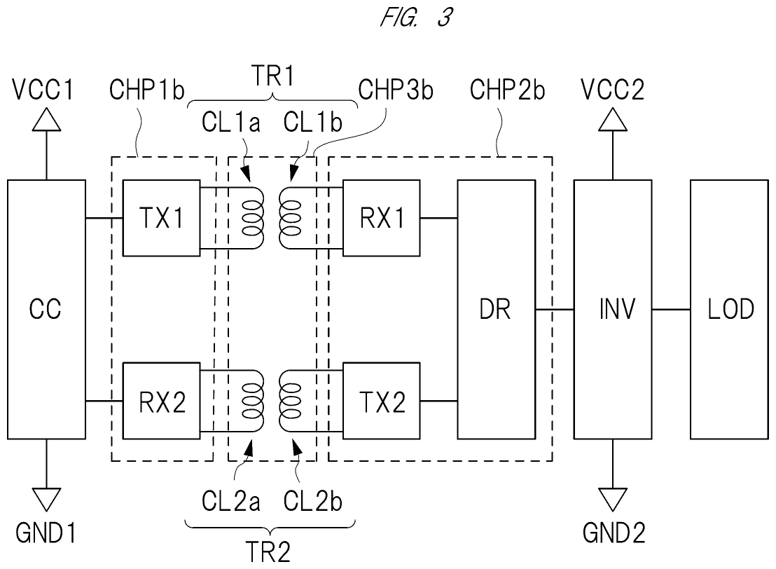

FIG. 1 is a diagram illustrating a configuration example of a driving controller (such as an inverter system) that drives a load circuit such as a motor. As illustrated in FIG. 1, the driving controller includes a control circuit CC, a transformer TR1, a transformer TR2, a driving circuit DR, and an inverter INV, and is electrically connected to a load circuit LOD.

A transmission circuit TX1 and a reception circuit RX1 transmit a control signal output from the control circuit (microcontroller) CC to the driving circuit (driver) DR. On the other hand, a transmission circuit TX2 and a reception circuit RX2 transmit a signal output from the driving circuit DR to the control circuit CC. The control circuit CC controls the driving circuit DR. The driving circuit DR operates the inverter INV that controls the load circuit LOD, based on the control of the control circuit CC.

A power supply potential VCC1 is supplied to the control circuit CC, and the control circuit CC is grounded by a ground potential GND1. On the other hand, a power supply potential VCC2 is supplied to the inverter INV, and the inverter INV is grounded by a ground potential GND2. In this case, for example, the power supply potential VCC1 is smaller than the power supply potential VCC2 supplied to the inverter INV.

The transformer TR1 is interposed between the transmission circuit TX1 and the reception circuit RX1. The transformer TR1 is made of a coil (inductor) CL1a and a coil CL1b that are inductively coupled (magnetically coupled) to each other. This manner makes a signal transmittable from the transmission circuit X1 to the reception circuit RX1 via the transformer TR1. As a result, the driving circuit DR receives a control signal output from the control circuit CC via the transformer TR1. The coil CL1a and the coil CL1b are electrically insulated from each other.

Thus, by the transformer TR1, the control signal is transmitted from the control circuit CC to the driving circuit DR while the transmission of electrical noise from the control circuit CC to the driving circuit DR is suppressed. This manner can suppress a malfunction of the driving circuit DR due to superimposition of the electrical noise on the control signal, thereby improving operational reliability of the semiconductor device.

Each of the coil CL1a and the coil CL1b functions as an inductor. The transformer TR1 functions as a magnetic coupling element made of the coil CL1a and the coil CL1b that are inductively coupled to each other.

Similarly, the transformer TR2 is interposed between the transmission circuit TX2 and the reception circuit RX2. The transformer TR2 is made of a coil CL2b and a coil CL2a that are inductively coupled to each other. This manner makes a signal transmittable from the transmission circuit TX2 to the reception circuit RX2 via the transformer TR2. As a result, the control circuit CC receives the signal output from the driving circuit DR via the transformer TR2.

Thus, by the transformer TR2, the signal is transmitted from the driving circuit DR to the control circuit CC while the transmission of electrical noise from the driving circuit DR to the control circuit CC is suppressed. This manner can suppress a malfunction of the control circuit CC due to superimposition of the electrical noise on the signal, thereby improving operational reliability of the semiconductor device.

The transformer TR1 is made of the coil CL1a and the coil CL1b, and the coil CL1a and the coil CL1b are not connected to each other via a conductor but are magnetically coupled to each other. Accordingly, when a current flows through the coil CL1a, an induced electromotive force is generated in the coil CL1b to generate an induced current flow in response to a change in the current. In this case, the coil CL1a is a primary coil, and the coil CL1b is a secondary coil. Thus, the transformer TR1 uses an electromagnetic induction phenomenon occurring between the coil CL1a and the coil CL1b. That is, the transmission of the signal from the transmission circuit TX1 to the coil CL1a in the transformer TR1 generates the current flow, and then the induced current generated in the coil CL1b in the transformer TR1 is detected by the reception circuit RX1. This allows the reception circuit RX1 to receive a signal corresponding to a control signal output from the transmission circuit TX1.

Similarly, the transformer TR2 is made of the coil CL2a and the coil CL2b, and the coil CL2a and the coil CL2b are not connected to each other via a conductor but are magnetically coupled to each other. Accordingly, when a current flows through the coil CL2b, an induced electromotive force is generated in the coil CL2a to generate an induced current flow in response to a change in the current. Thus, the transmission of the signal from the transmission circuit TX2 to the coil CL2b in the transformer TR2 generates the current flow, and then the induced current generated in the coil CL2a in the transformer TR2 is detected by the reception circuit RX2. This allows the reception circuit RX2 to receive a signal corresponding to a control signal output from the transmission circuit TX2.

Signal transmission/reception between the control circuit CC and the driving circuit DR is performed through a route from the transmission circuit TX1 to the reception circuit RX1 via the transformer TR1 and a route from the transmission circuit TX2 to the reception circuit RX2 via the transformer TR2. That is, since the signal transmitted by the transmission circuit TX1 is received by the reception circuit RX1 while the signal transmitted by the transmission circuit TX2 is received by the reception circuit RX2, the signal transmission/reception between the control circuit CC and the driving circuit DR is performed. As described above, the transformer TR1 is interposed to transmit the signal from the transmission circuit TX1 to the reception circuit RX1, while the transformer TR2 is interposed to transmit the signal from the transmission circuit TX2 to the reception circuit RX2. This allows the driving circuit DR to drive the inverter INV for operating the load circuit LOD in response to the signal transmitted from the control circuit CC. Each of the routes is referred to as channel. The driving controller illustrated in FIG. 1 has two channels.

A voltage level of a reference potential of the control circuit CC and a voltage level of a reference potential of the driving circuit DR are different from each other. That is, in the control circuit CC, the reference potential is fixed to a ground potential GND1, while the driving DR is electrically connected to the inverter INV, as illustrated in FIG. 1. The inverter INV includes, for example, a high-side IGBT (insulated gate bipolar transistor) and a low-side IGBT. In the inverter INV, the on/off control of the high-side IGBT and the on/off control of the low-side IGBT are performed by the driving circuit DR, thereby achieving control of the load circuit LOD by the inverter INV. Specifically, the on/off control of the high-side IGBT is performed by control of a potential applied to a gate electrode of the high-side IGBT by the driving circuit DR. Similarly, the on/off control of the low-side IGBT is performed by control of a potential applied to a gate electrode of the low-side IGBT by the driving circuit DR.

For example, the on control of the low-side IGBT is achieved by, with reference to the emitter potential (0 V) of the low-side IGBT connected to the ground potential GND2, applying “the emitter potential (0 V)+a threshold voltage (15 V)” to the gate electrode. On the other hand, for example, the off control of the low-side IGBT is achieved by, with reference to the emitter potential (0 V) of the low-side IGBT connected to the ground potential GND2, applying “the emitter potential (0 V)” to the gate electrode. Therefore, the on/off control of the low-side IGBT is performed depending on whether or not the threshold voltage (15V) is applied to the gate electrode with reference to 0 V as the reference voltage.

On the other hand, for example, the on control of the high-side IGBT is also performed, with reference to an emitter potential of the high-side IGBT as a reference potential, depending on whether or not “the reference potential+the threshold voltage (15 V)” is applied to the gate electrode. However, the emitter potential of the high-side IGBT is not fixed to the ground potential GND2 as different from the emitter potential of the low-side IGBT. That is, in the inverter INV, the high-side IGBT and the low-side IGBT are connected in series between the power supply potential VCC2 and the ground potential GND2. In the inverter INV, the off control of the low-side IGBT is achieved when the high-side IGBT is turned on, while the on control of the low-side IGBT is achieved when the high-side IGBT is turned off. Therefore, when the high-side IGBT is turned off, the low-side IGBT is turned on. Accordingly, the emitter potential of the high-side IGBT is turned to the ground potential GND2 by the turned-on low-side IGBT. On the other hand, when the high-side IGBT is turned on, the low-side IGBT is turned off. Accordingly, the emitter potential of the high-side IGBT is turned to the power supply potential VCC2. At this time, the on/off control of the high-side IGBT is performed, with reference to the emitter potential of the high-side IGBT as the reference potential, depending on whether or not “the reference potential+the threshold voltage (15 V)” is applied to the gate electrode.

As described above, the emitter potential of the high-side IGBT varies depending on whether the high-side IGBT is turned on or off. That is, the emitter potential of the high-side IGBT varies from the ground potential GND2 (0 V) to the power supply potential VCC2 (such as 800 V). Therefore, in order to turn on the high-side IGBT, “the reference potential (800 V)+the threshold voltage (15 V)” needs to be applied to the gate electrode with reference to the emitter potential of the high-side IGBT as the reference potential. Accordingly, in the driving circuit DR that performs the on/off control of the high-side IGBT, the emitter potential of the high-side IGBT needs to be evaluated. Therefore, the driving circuit DR is configured to receive the emitter potential of the high-side IGBT as its input. As a result, the driving circuit DR receives the reference potential of 800 V as its input, and the driving circuit DR performs control to turn on the high-side IGBT by applying the threshold voltage (15V) to the gate electrode of the high-side IGBT with reference to the reference potential of 800 V. Therefore, the high potential of about 800 V is applied to the driving circuit DR.

Thus, the driving controller includes the control circuit CC that handles a low potential (several tens of volts) and the driving circuit DR that handles a high potential (several hundreds of volts). That is, the control circuit CC is driven at a predetermined voltage, while the driving circuit DR is driven at a voltage different from the voltage. Accordingly, signal transmission between the control circuit CC and the driving circuit DR needs to be performed between circuits that are respectively driven at different potentials.

In this regard, the signal transmission between the control circuit CC and the driving circuit DR is performed via the transformer TR1 and the transformer TR2. Accordingly, the signals can be transmitted between the circuits that are respectively driven at different potentials.

As described above, a large potential difference may occur between the primary coil and the secondary coil in the transformer TR1 and the transformer TR2. Conversely, since the large potential difference may occur, the primary coil and the secondary coil that are not connected to each other via the conductor but are magnetically coupled to each other are used for the signal transmission. Therefore, in forming the transformer TR1, it is important to make a withstand voltage between the coil CL1a and the coil CL1b as high as possible from the viewpoint of improving the operational reliability of the semiconductor device. Similarly, in forming the transformer TR2, it is important to make a withstand voltage between the coil CL2b and the coil CL2a as high as possible from the viewpoint of improving the operational reliability of the semiconductor device.

### Example of Signal Transmission

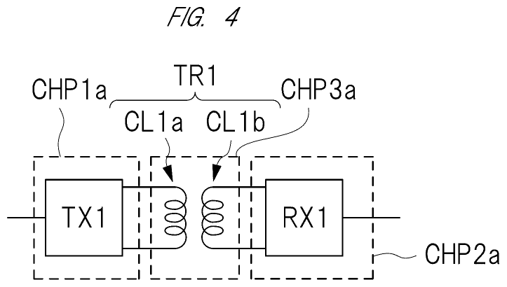

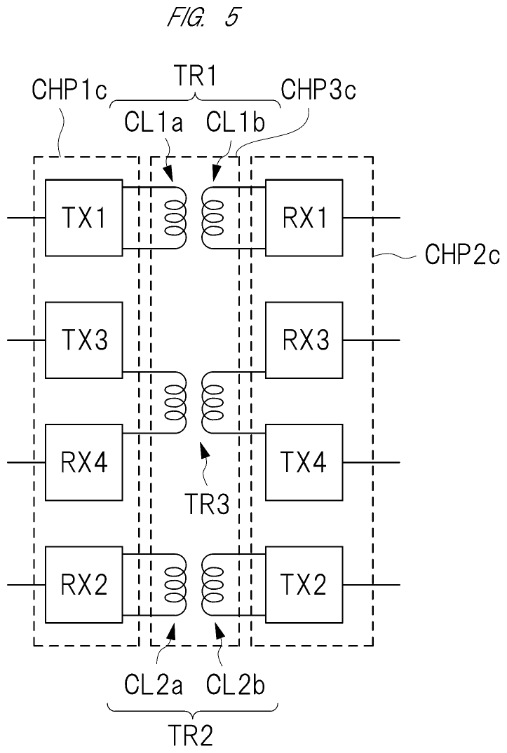

FIG. 2 is an explanatory diagram illustrating an example of the signal transmission. In FIG. 2, the transmission circuit TX1 extracts an edge portion of a square wave signal SG1 input to the transmission circuit TX1 to generate a signal SG2 having a certain pulse width, and transmits the signal SG2 to the coil CL1a (primary coil) in the transformer TR1. When a current based on the signal SG2 flows through the coil CL1a (primary coil) in the transformer TR1, a signal SG3 corresponding thereto is flown through the coil CL1b (secondary coil) in the transformer TR1 by an induced electromotive force. The signal SG3 is amplified by the reception circuit RX1 and is further modulated into a square wave, so that a square wave signal SG4 is output from the reception circuit RX1. In this manner, the signal SG4 corresponding to the signal SG1 input to the transmission circuit TX1 can be output from the reception circuit RX1. Thus, the signals can be transmitted from the transmission circuit TX1 to the reception circuit RX1. The signals can be similarly transmitted from the transmission circuit TX2 to the reception circuit RX2.

### Three-Chip Configuration

The following is explanation on a configuration in which a transmission/reception circuit unit in the above-described driving controller is made of three semiconductor chips.

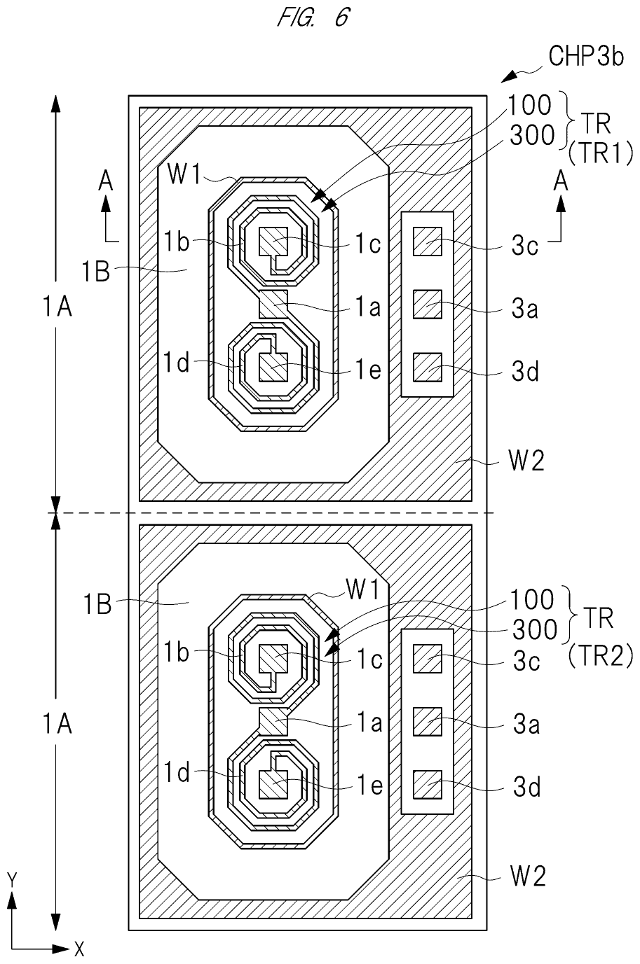

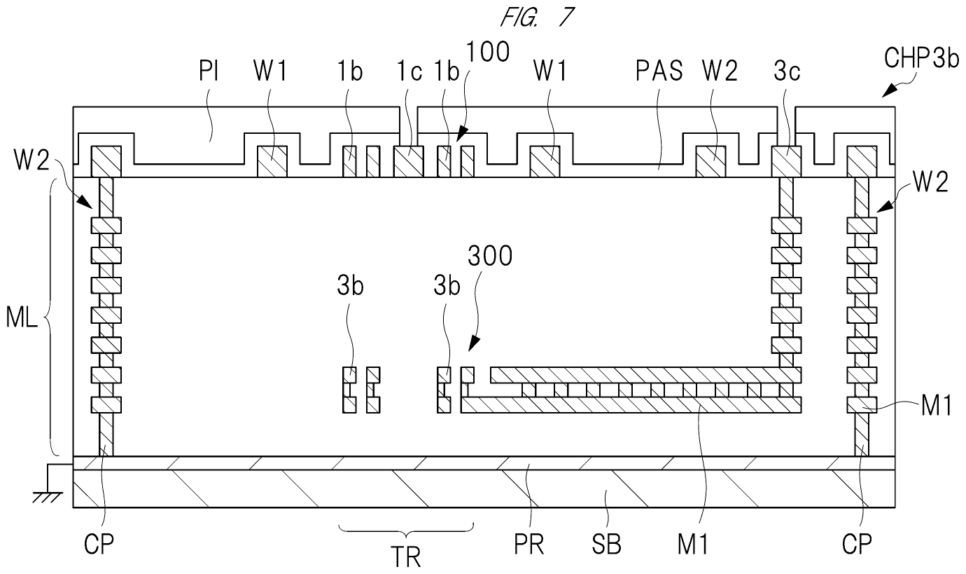

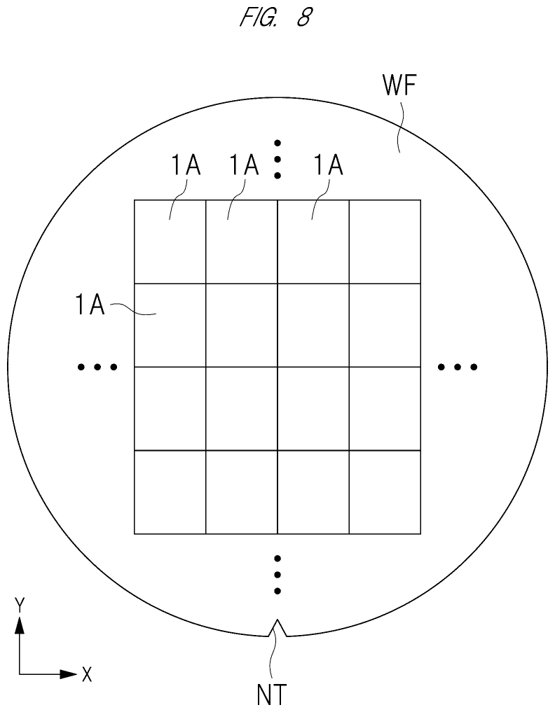

FIG. 3 is a diagram illustrating a three-chip configuration. In FIG. 3, the transmission circuit TX1 and the reception circuit RX2 are formed in a primary-side semiconductor chip CHP1b. Also, the driving circuit DR, the reception circuit RX1, and the transmission circuit TX2 are formed in a secondary-side semiconductor chip CHP2b. On the other hand, the transformer TR1 and the transformer TR2 are formed in a semiconductor chip CHP3b.

In this manner, in the three-chip configuration, even if a design of the semiconductor chip CHP1b or the semiconductor chip CHP2b is changed, the semiconductor chip CHP3b can be used without being changed in the design. Accordingly, the three-chip configuration can increase variation of the available semiconductor chips CHP1b and CHP2b. In other words, the versatility of the semiconductor chip CHP3b including the transformer TR1 and the transformer TR2 can be enhanced. Further, the semiconductor chip CHP3b including the transformer TR1 and the transformer TR2 does not include a transistor, and therefore, can be formed only by a wiring step. As a result, a manufacturing process can be simplified. Therefore, the three-chip configuration enables a reduction in manufacturing cost, thereby enabling manufacturing of a highly competitive product.

The semiconductor chip CHP1b, the semiconductor chip CHP2b, and the semiconductor chip CHP3b are sealed with mold resin, and are manufactured as a single semiconductor package (chip). The semiconductor chip CHP3b including the transformer TR1 and the transformer TR2 is referred to as a transformer chip. The driving controller includes, for example, six transformers between the control circuit CC and the driving circuit DR. That is, two sets each including the semiconductor chip CHP1b, the semiconductor chip CHP2b, and the semiconductor chip CHP3b illustrated in FIG. 3 are further connected between the control circuit CC and the driving circuit DR.

The driving controller illustrated in FIG. 3 has a route extending from the transmission circuit TX1 to the reception circuit RX1 via the transformer TR1 and a route extending from the transmission circuit TX2 to the reception circuit RX2 via the transformer TR2 as routes for the signal transmission/reception. The driving controller has, for example, two channels between the (primary-side) control circuit CC and the (secondary-side) driving circuit DR.

### Another Example of Three-Chip Configuration

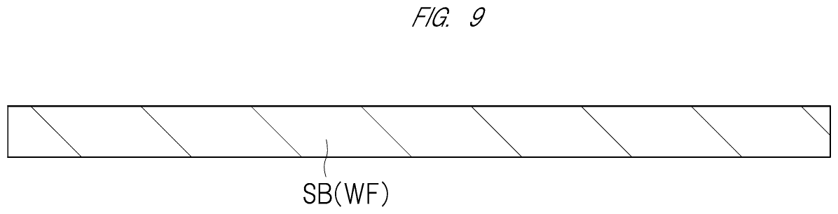

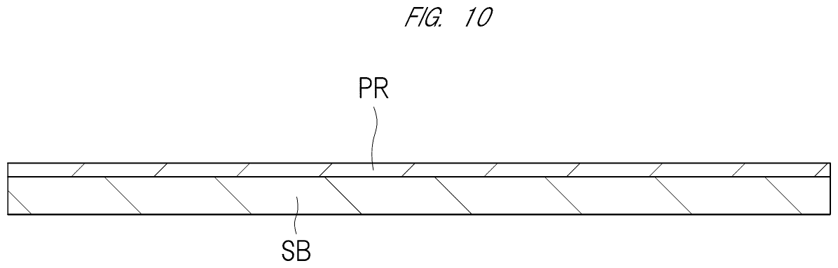

FIG. 3 illustrates a configuration using a transformer chip including two transformers. The present invention is not limited to this, and the transformer chip may include one or three transformers. In a semiconductor chip CHP2a and a semiconductor chip CHP2c respectively illustrated in the following FIGS. 4 and 5, illustration of the driving circuit DR is omitted.

FIG. 4 illustrates a three-chip configuration in which the number of transformers formed in the transformer chip is one. In this case, the transmission circuit TX1 is formed in the semiconductor chip CHP1a, the transformer TR1 is formed in the semiconductor chip CHP3a, and the reception circuit RX1 is formed in the semiconductor chip CHP2a. In a chip including the semiconductor chip CHP1a, the semiconductor chip CHP2a, and the semiconductor chip CHP3a, signals are transmitted and received through a route extending from the transmission circuit TX1 to the reception circuit RX1 via the transformer TR1. That is, the driving controller illustrated in FIG. 4 has one channel for the signal transmission from the primary side to the secondary side.

FIG. 5 illustrates a three-chip configuration in which the number of transformers formed in the transformer chip is three. The transmission circuit TX1, a transmission circuit TX3, a reception circuit RX4, and the reception circuit RX2 are formed in a semiconductor chip CHP1c. The transformer TR1, a transformer TR3, and the transformer TR2 are formed in a semiconductor chip CHP3c. The transformer TR3 includes a primary coil and a secondary coil as similar to the transformer TR1. The reception circuit RX1, a reception circuit RX3, a transmission circuit TX4, and the transmission circuit TX2 are formed in a semiconductor chip CHP2c. In a chip including the semiconductor chip CHP1c, the semiconductor chip CHP2c, and the semiconductor chip CHP3c, signals are transmitted and received through four routes. Two of the four routes are respectively a route extending from the transmission circuit TX1 to the reception circuit RX1 via the transformer TR1 and a route extending from the transmission circuit TX2 to the reception circuit RX2 via the transformer TR2. The other two routes are respectively a route extending from the transmission circuit TX3 to the reception circuit RX3 via the transformer TR3 and a route extending from the transmission circuit TX4 to the reception circuit RX4 via the transformer TR3. That is, in two of the four routes, signals are bidirectionally transmitted and received by using one channel via one transformer TR3. That is, a driving controller illustrated in FIG. 5 has a total of three channels that are a channel for signal transmission from the primary side to the secondary side, a channel for signal transmission from the secondary side to the primary side, and a channel for signal bidirectional transmission between the primary side and the secondary side.

In the driving controller that transmits and receives signals through four routes, the number of transformers formed in the transformer chip is set to three, thereby reducing the manufacturing cost of the semiconductor device. The present invention is not limited to such a configuration, and four transformers may be formed in the transformer chip to correspond to the four routes. As described above, the number of transformers formed in the transformer chip varies depending on an application of the driving controller. The number of transformers to be formed in the transformer chip is not limited to one to four described above, but may be five or more.

### Structure of Semiconductor Device

On the premise of the three-chip configuration, a configuration of the semiconductor chip (transformer chip) CHP3b as the semiconductor device according to the first embodiment will be described below. Here, as similar to FIG. 3, a configuration of a transformer chip including two transformers will be described.

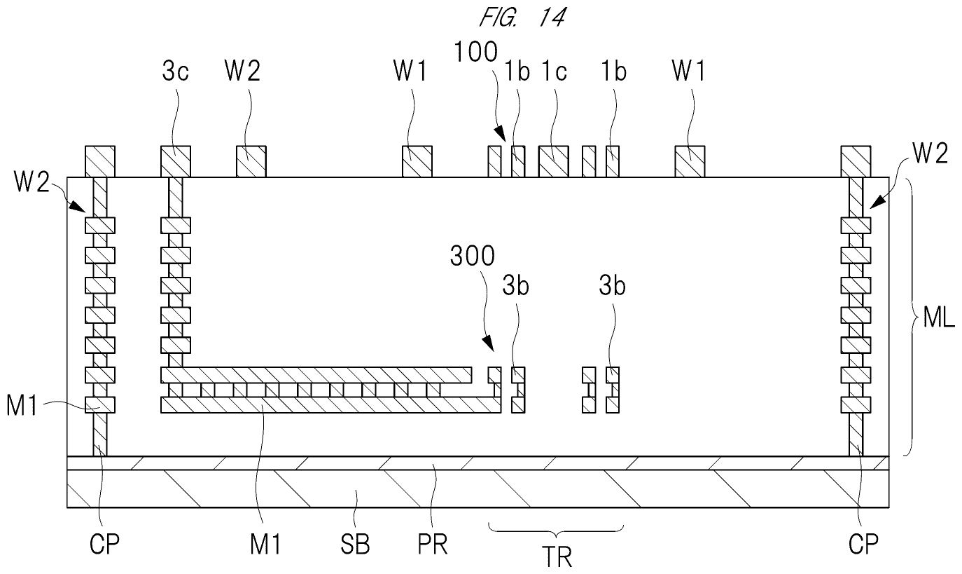

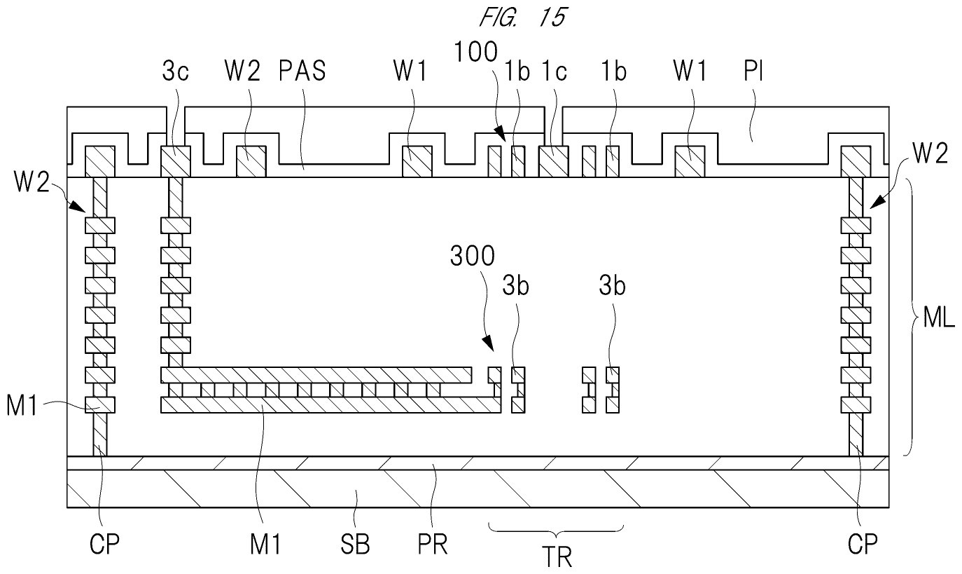

FIG. 6 is a plan view illustrating the semiconductor chip CHP3b in the first embodiment. In FIG. 6, a conductor pattern on a multilayer wiring layer formed in the semiconductor chip CHP3b is illustrated with hatching, and an insulating film included in the multilayer wiring layer is illustrated in a region other than the conductor pattern. In FIG. 6, illustration of a protective film and the like formed over the multilayer wiring layer and the conductor pattern is omitted.

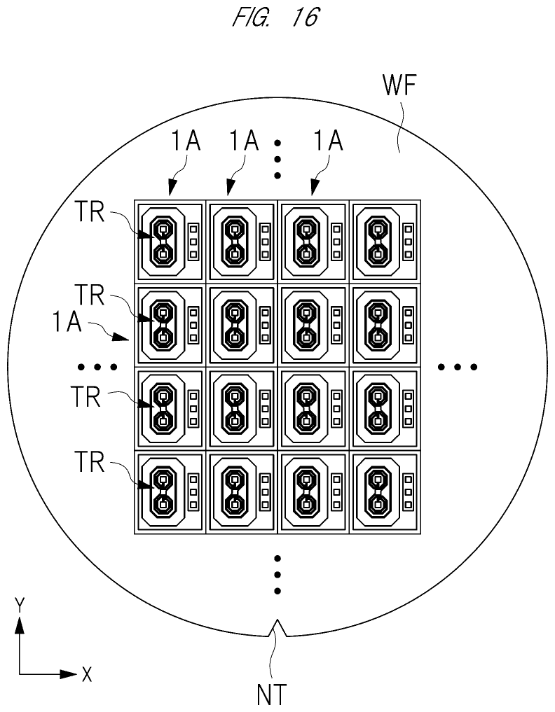

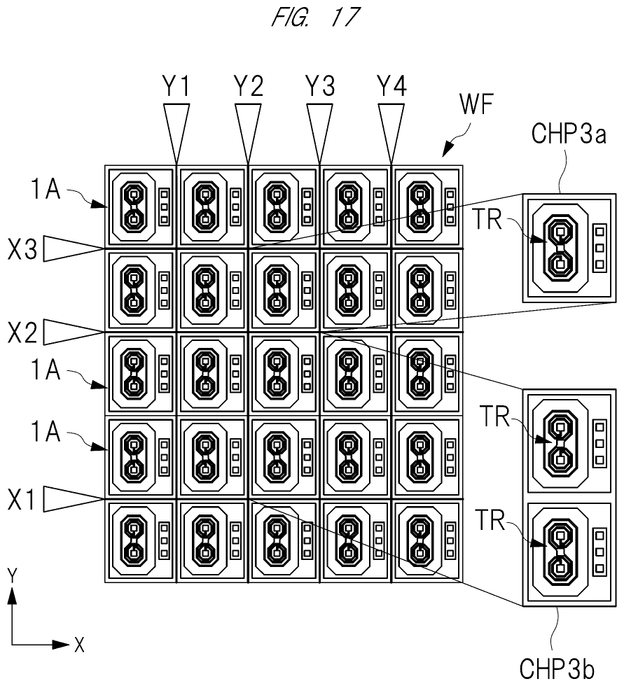

As illustrated in FIG. 6, a planar shape of the semiconductor chip CHP3b is a rectangular shape. In plan view, the semiconductor chip CHP3b includes two element regions 1A arranged in a Y-direction. Since the two element regions 1A respectively have the same structures as each other, the structure of one element region 1A will be described in detail below. An X-direction is along a main surface of a semiconductor substrate SB (see FIG. 7) configuring the semiconductor chip CHP3b. The Y-direction is along the main surface of the semiconductor substrate SB (see FIG. 7) configuring the semiconductor chip CHP3b. In plan view, the Y-direction is perpendicular to the X-direction. In the semiconductor chip CHP3b, the element regions 1A are arranged in the Y-direction, and the element regions 1A are not arranged in the X-direction in plan view.

A conductor pattern (guard ring) W2 is formed on a peripheral edge of each of the element regions 1A. The conductor pattern W2 is made of a wiring formed to surround the element region 1A in plan view. The conductor patterns W2 respectively formed in the element regions 1A adjacent to each other are spaced apart from each other. In plan view, a conductor pattern W1 is formed to be surrounded by the conductor pattern W2. The conductor pattern W1 is made of a wiring formed to surround the element region 1A in plan view. In plan view, an upper layer inductor (upper layer coil) 100 is formed to be surrounded by the conductor pattern W1. That is, the upper layer inductor 100 is also surrounded by the conductor pattern W2 in plan view. The conductor patterns W1 respectively formed in the element regions 1A adjacent to each other in the semiconductor chip CHP3b are spaced apart from each other.

The upper layer inductor 100 includes a tap pad 1a, a spiral wiring 1b connected to the tap pad 1a, a spiral wiring 1d, a transformer pad 1c connected to the spiral wiring 1b, and a transformer pad 1e connected to the spiral wiring 1d. The tap pad 1a, the spiral wiring 1b, the spiral wiring 1d, the transformer pad 1c, and the transformer pad 1e are made of a single unified conductor pattern. The upper layer inductor 100 and a lower layer inductor 300 described later configure the transformer TR formed in the element region 1A. The two transformers TR illustrated in FIG. 6 respectively correspond to the transformer TR1 and the transformer TR2 illustrated in FIG. 3. The upper layer inductor 100 corresponds to the coil CL2a illustrated in FIG. 3, and the lower layer inductor 300 corresponds to the coil CL2b illustrated in FIG. 3.

In plan view, the spiral wiring 1b extends to surround the transformer pad 1c, and the spiral wiring 1d extends to surround the transformer pad 1e. The tap pad 1a is positioned between the transformer pad 1c and the transformer pad 1e in the Y-direction. The tap pad 1a may be arranged at a position that shifts in the X-direction from a middle between the transformer pad 1c and transformer pad 1e in the Y-direction.

In plan view, a tap pad 3a, a transformer pad 3c, and a transformer pad 3d are formed to be surrounded by the conductor pattern W2. The tap pad 3a, the transformer pad 3c, and the transformer pad 3d are arranged in a region surrounded by the conductor pattern W2 in plan view, but are arranged at positions different from a region surrounded by the conductor pattern W1 and the upper layer inductor 100. However, the conductor pattern W1, the upper layer inductor 100, the tap pad 3a, the transformer pad 3c, and the transformer pad 3d may be included in a single region surrounded by the conductor pattern W2.

The tap pad 3a, the transformer pad 3c, and the transformer pad 3d are connected to a lower layer inductor (see FIG. 7). The lower layer inductor is formed below the upper layer inductor 100. The upper layer inductor 100 is paired with the lower layer inductor directly below the upper layer inductor 100. The tap pad 3a, the transformer pad 3c, and the transformer pad 3d are formed in the same layer as that of the upper layer inductor 100. The conductor pattern W1, the conductor pattern W2, the upper layer inductor 100, the tap pad 3a, the transformer pad 3c, and the transformer pad 3d are formed in the same layer, and are formed at the same height from a main surface of the semiconductor substrate SB illustrated in FIG. 7 in a direction perpendicular to the main surface.

For example, the reference potential of about 800 V is applied to the upper layer inductor 100 to be electrically connected to the control circuit CC. On the other hand, the reference potential of about 0 V is applied to the lower layer inductor to be electrically connected to the driving circuit DR and the tap pad 3a, the transformer pad 3c, and the transformer pad 3d. That is, to the lower layer inductor paired with the upper layer inductor 100, the reference potential different from the reference potential applied to the upper layer inductor 100 is applied. The reference potential of, for example, about 800 V is applied to the conductor pattern W1. The reference potential of, for example, about 0 V is applied to the conductor pattern W2.

Accordingly, a large potential difference occurs between the upper layer inductor 100 and the conductor pattern W2 when the driving controller operates. Therefore, the upper layer inductor 100 and the conductor pattern W2 are spaced apart from each other for the purpose of preventing the dielectric breakdown between the upper layer inductor 100 and the conductor pattern W2. That is, between the upper layer inductor 100 and the conductor pattern W2, there is a region 1B where no wiring (conductor pattern) is formed. The region 1B surrounds the upper layer inductor 100 in plan view.

Then, FIG. 7 is a cross-sectional view of the semiconductor chip taken along a line A-A illustrated in FIG. 6. In FIG. 7, hatching added to the insulating film is omitted to make the drawing understandable.

As illustrated in FIG. 7, the semiconductor chip CHP3b includes the p-type semiconductor substrate SB. In the semiconductor chip CHP3b, a p-type semiconductor region PR having a predetermined depth from the main surface of the semiconductor substrate SB and having a higher impurity concentration than that of the semiconductor substrate SB is formed. A multilayer wiring layer ML is formed on the p-type semiconductor region PR. The p-type semiconductor region PR is connected to a fixed potential (such as a ground potential). The conductor pattern W2 is formed as a wiring in an uppermost layer of the multilayer wiring layer ML. That is, the conductor pattern W2 includes alternately-stacked wirings and conductive connection sections (contact plugs, vias) formed in the multilayer wiring layer ML, and a pattern (see FIG. 6) formed on the multilayer wiring layer ML. A conductive connection section CP configuring the conductor pattern W2 in the multilayer wiring layer ML is connected to the p-type semiconductor region PR.

A lower layer inductor (lower layer coil) 300 including a spiral wiring 3b is formed in the multilayer wiring layer ML. The spiral wiring 3b is made of a conductor pattern overlapping the spiral wiring 1b in plan view. In a region not illustrated in FIG. 7, a spiral wiring made of a conductor pattern overlapping the spiral wiring 1d (see FIG. 6) in plan view is formed. The spiral wiring 3b directly below the spiral wiring 1b and a spiral wiring directly below the spiral wiring 1d are connected to each other, to configure the lower layer inductor 300. The lower layer inductor 300 and the transformer pad 3c are connected to each other via a wiring formed in the multilayer wiring layer ML. That is, the spiral wiring 3b is electrically connected to the transformer pad 3c formed in the uppermost layer of the multilayer wiring layer ML. The lower layer inductor 300 is electrically connected to the tap pad 3a, the transformer pad 3c, and the transformer pad 3d (see FIG. 6) via a wiring formed in the multilayer wiring layer ML.

Further, the upper layer inductor 100 is formed on the multilayer wiring layer ML. That is, the upper layer inductor 100 is formed over the lower layer inductor 300, and the upper layer inductor 100 includes the tap pad 3a, the spiral wiring 1b, the spiral wiring 1d, the transformer pad 1c, and the transformer pad 1e. The upper layer inductor 100 and the lower layer inductor 300 that overlap each other in plan view are magnetically coupled to each other, to configure a single transformer TR.

A surface protective film PAS and a polyimide resin film PI are sequentially formed on the multilayer wiring layer ML to cover the upper layer inductor 100, the conductor pattern W1, and the conductor pattern W2. A stacked film made of the surface protective film PAS and the polyimide resin film PI has a plurality of openings extending from an upper surface of the polyimide resin film PI to a lower surface of the surface protective film PAS. At respective bottoms of the plurality of openings, a part of a surface of the transformer pad 3c and a part of a surface of the transformer pad 1c are exposed. Note that the surface protective film PAS is made of a silicon oxide film and a silicon nitride film.

FIGS. 6 and 7 illustrate the case of two element regions 1A formed in the semiconductor chip (transformer chip), that is, the case of two transformers formed in the semiconductor chip. On the other hand, in a case of only one transformer formed in the semiconductor chip as illustrated in FIG. 4, only one element region 1A illustrated in FIG. 6 is formed in the semiconductor chip. In a case of three transformers formed in the semiconductor chip as illustrated in FIG. 5, three element regions 1A illustrated in FIG. 6 are formed side by side in the Y-direction in the one semiconductor chip.

### Method of Manufacturing Semiconductor Device

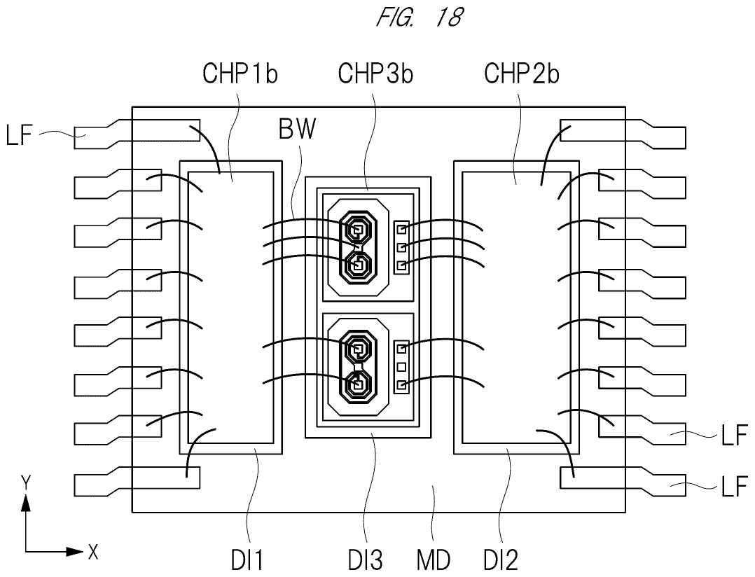

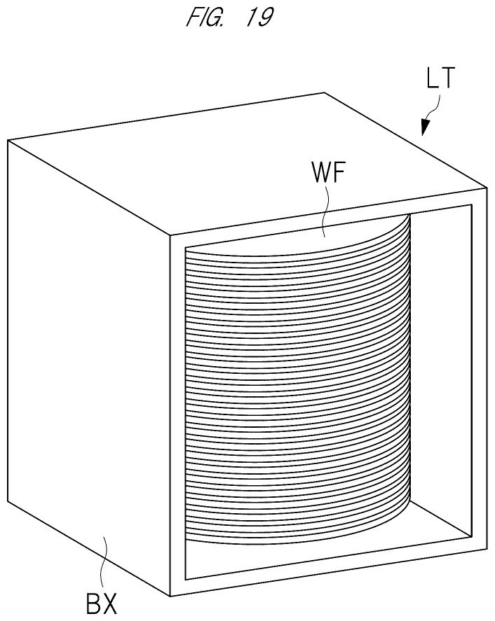

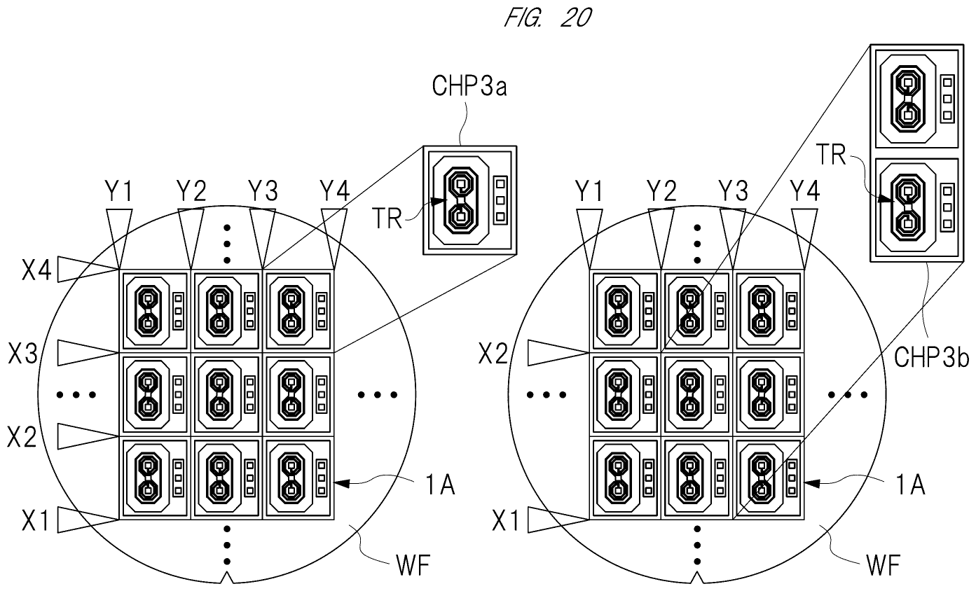

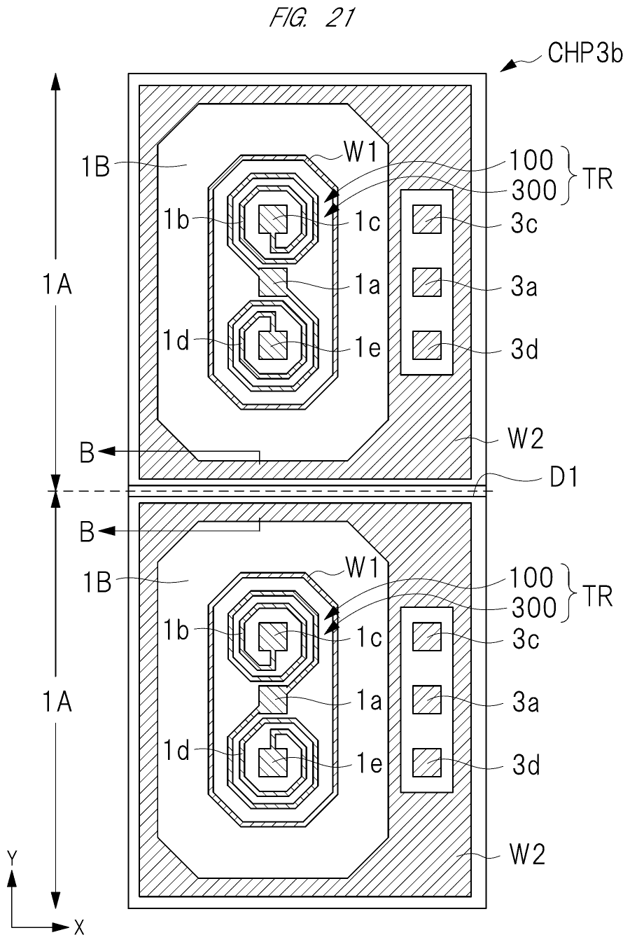

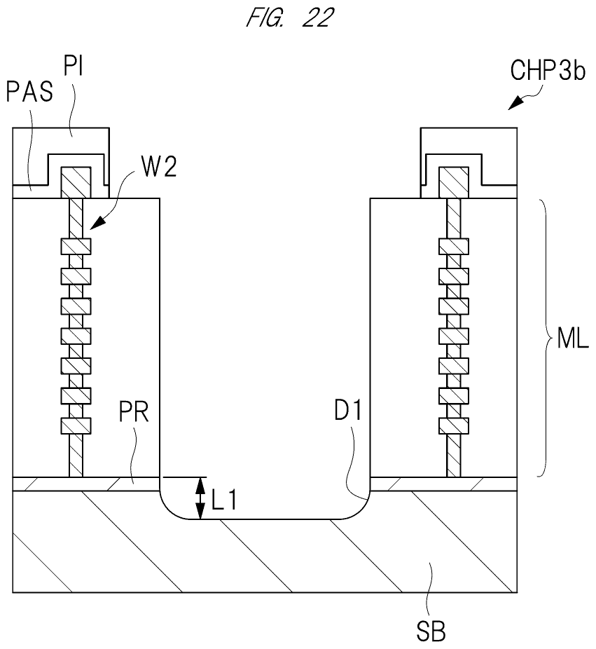

A method of manufacturing the semiconductor device according to the first embodiment will be described below with reference to FIGS. 8 to 17. FIGS. 8, 16, and 17 are respectively plan views in steps of manufacturing the semiconductor device according to the first embodiment. FIGS. 9 to 15 are respectively cross-sectional views in steps of manufacturing the semiconductor device according to the first embodiment.

First, as illustrated in FIGS. 8 and 9, the p-type semiconductor substrate SB (semiconductor wafer WF) having the main surface (upper surface) and a back surface (lower surface) on the opposite side to the main surface is prepared. The semiconductor wafer WF has a substantially circular planar shape, and has a notch NT at an end of its part. On the main surface of the semiconductor wafer WF, a plurality of element regions 1A are arranged in a matrix form in the X-direction and the Y-direction.

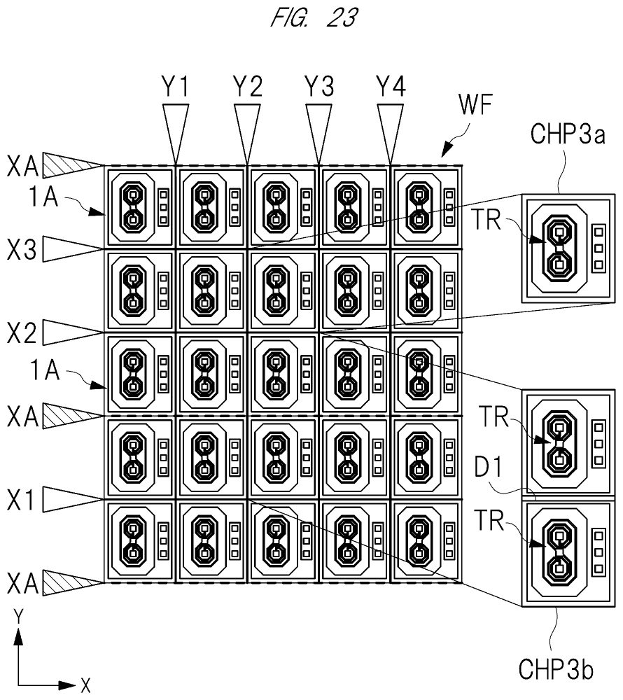

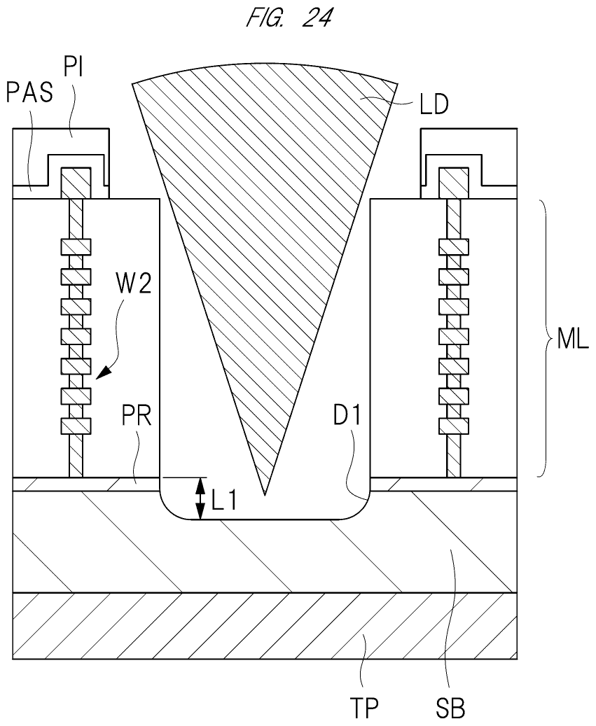

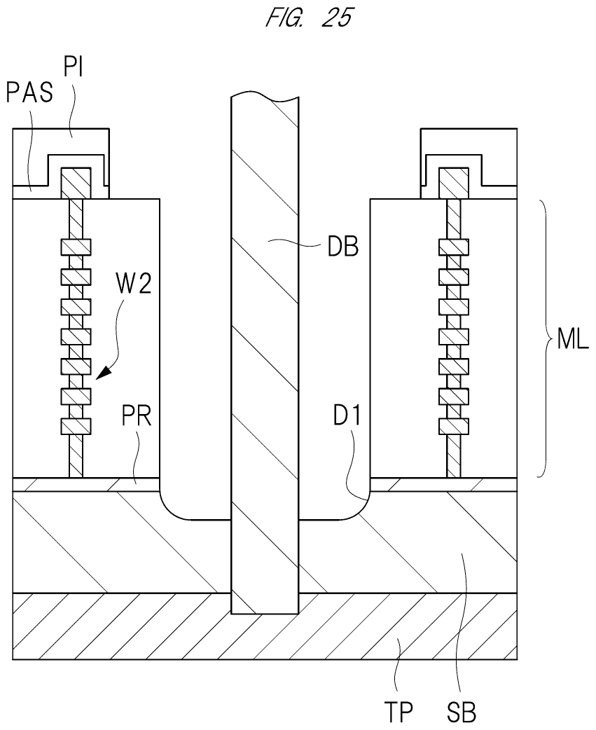

Then, as illustrated in FIG. 10, p-type impurities are introduced into the semiconductor substrate SB by, for example, an ion implantation method. In this manner, a p-type semiconductor region PR having a predetermined depth from the main surface of the semiconductor substrate SB is formed in the semiconductor substrate SB.

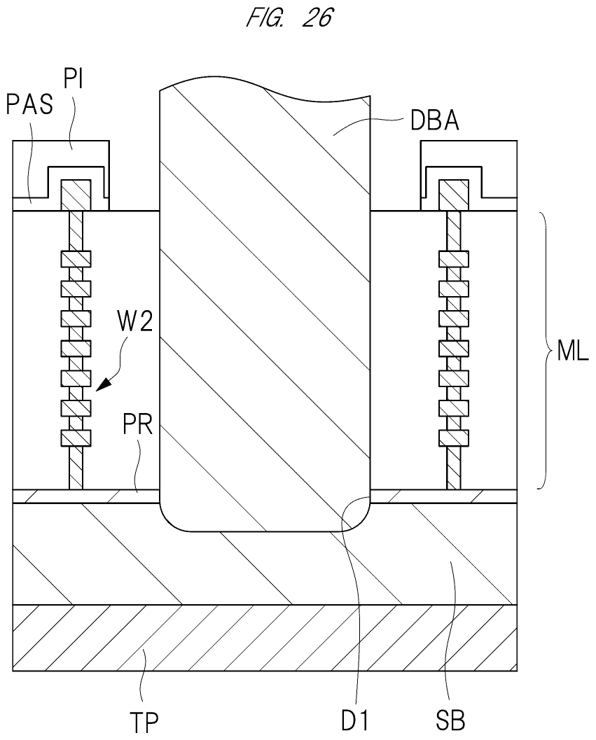

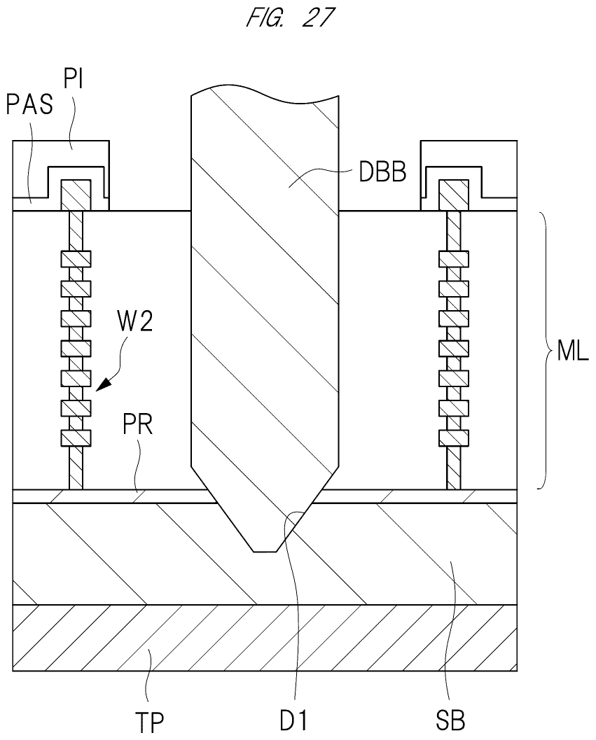

Then, as illustrated in FIG. 11, an insulating film IF1 is formed on the main surface of the semiconductor substrate SB. The insulating film IF1 is mainly made of, for example, silicon oxide, and is formed by, for example, a CVD (chemical vapor deposition) method. Then, an opening that penetrates the insulating film IF1 is formed by a photolithography technique and an etching method. Then, a conductive connection section (contact plug) CP, which fills the opening of the insulating film IF1, is formed. The conductive connection section CP is made of, for example, a conductive film remaining in the opening, the conductive film being formed by forming the conductive film to fill the opening by a sputtering method and then removing the conductive film on the insulating film IF1.

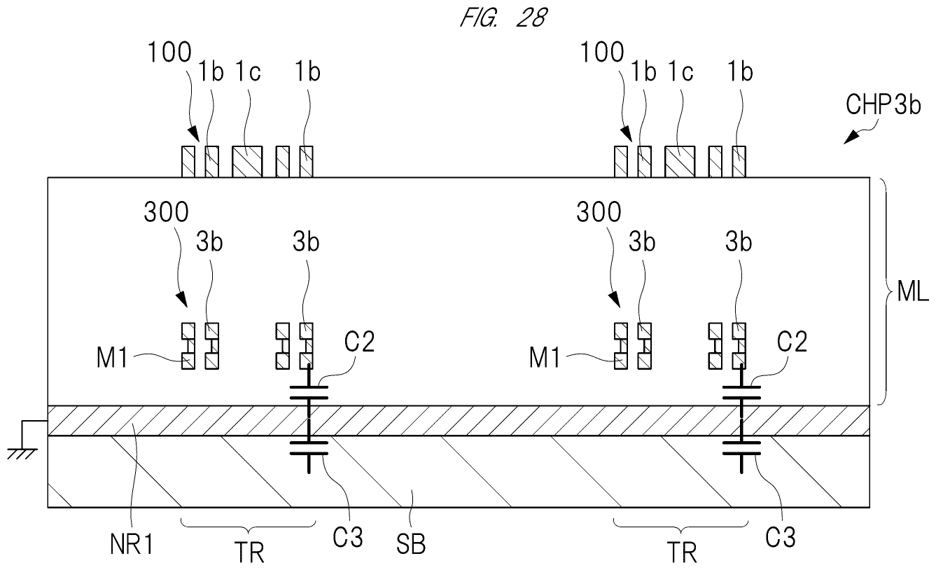

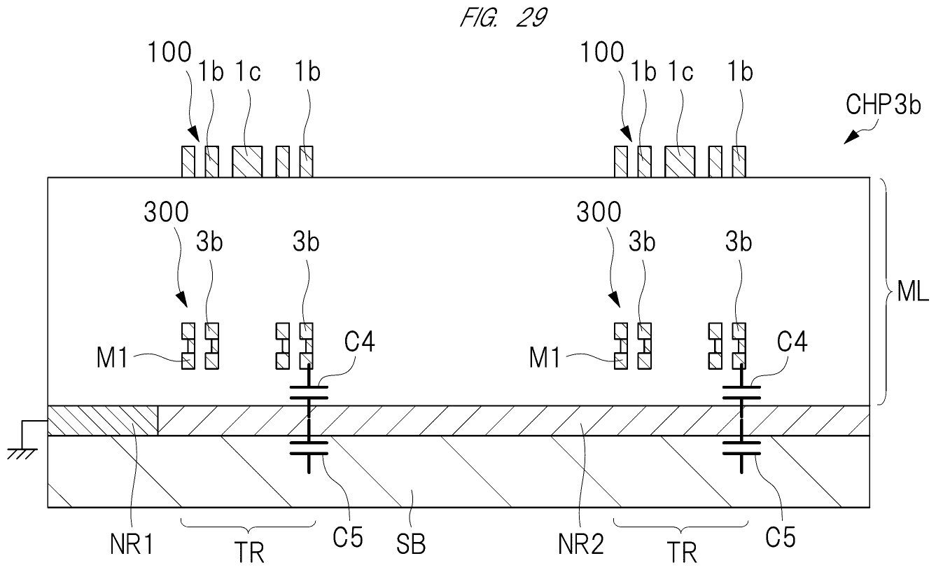

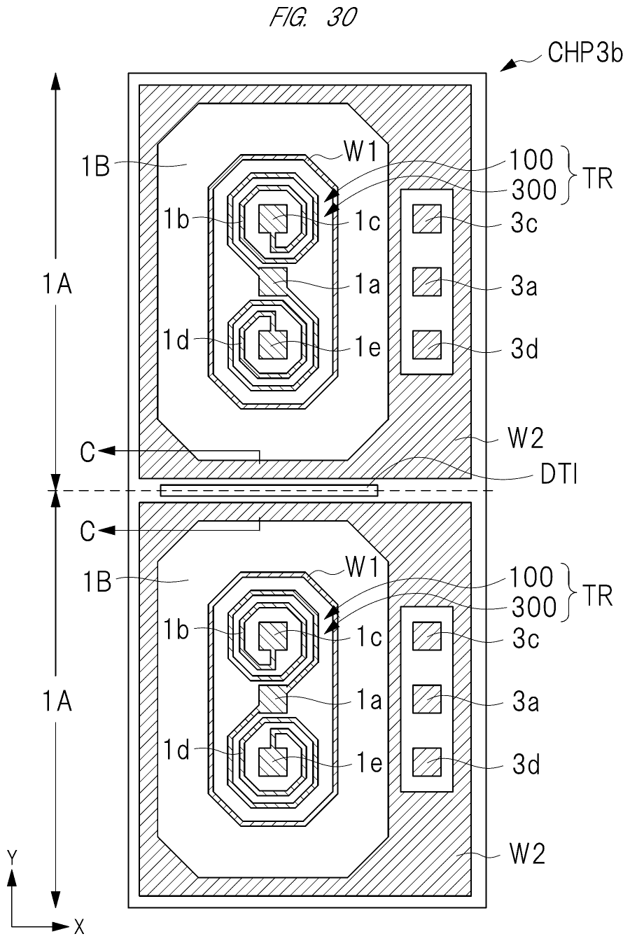

Then, as illustrated in FIG. 12, a plurality of wirings M1 are formed on the insulating film IF1 and the conductive connection section CP. The plurality of wirings M1 can be formed by, for example, forming a conductive film by a sputtering method and then patterning the conductive film by a photolithography technique and an etching method. The plurality of wirings M1 are made of, for example, aluminum (Al).

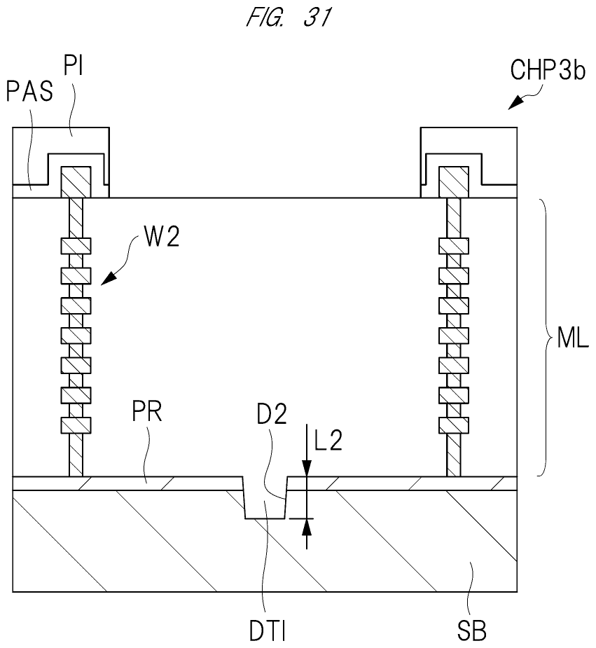

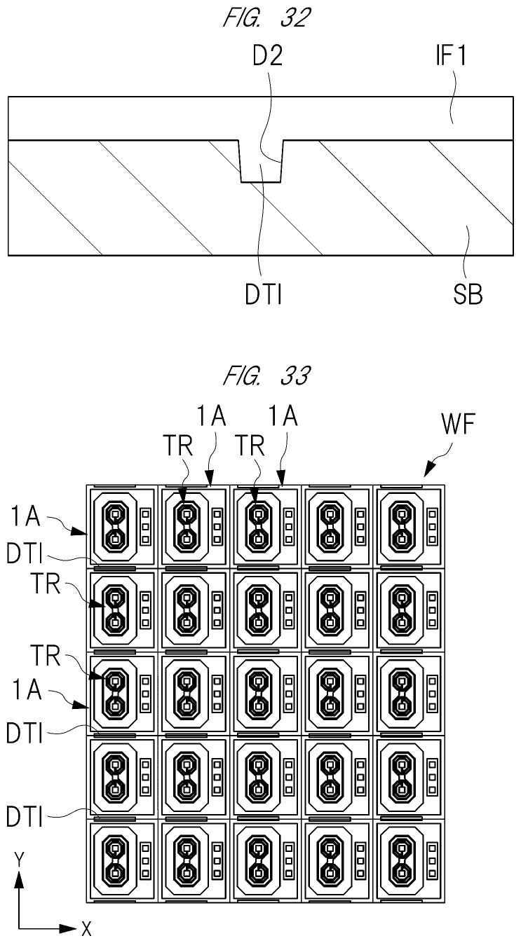

Then, as illustrated in FIG. 13, a step of forming the conductive connection section described with reference to FIG. 11 and a step of forming the wirings described with reference to FIG. 12 are repeated. In this manner, the multilayer wiring layer ML including the plurality of insulating films, the plurality of conductive connection sections, and the plurality of wirings are formed on the semiconductor substrate SB. Note that FIG. 13 illustrates the plurality of insulating films stacked to be unified. The lower layer inductor 300 made of the spiral wirings 3b and the like described with reference to FIG. 7 is formed in the multilayer wiring layer ML.

Then, as illustrated in FIG. 14, the conductor pattern W1, the conductor pattern W2, the upper layer inductor 100, the tap pad 3a, the transformer pad 3c, and the transformer pad 3d (see FIG. 6) are formed on the multilayer wiring layer ML. The conductor patterns can be formed by, for example, forming a conductive film on a multilayer wiring layer by a sputtering method and then patterning the conductive film a by photolithography technique and an etching method. In this manner, the transformer TR made of the upper layer inductor 100 and the lower layer inductor 300 is formed.

Then, as illustrated in FIG. 15, the surface protective film PAS and the polyimide resin film PI are sequentially formed on the multilayer wiring layer ML to cover the conductor pattern W1, the conductor pattern W2, the upper layer inductor 100, the tap pad 3a, the transformer pad 3c, and the transformer pad 3d (see FIG. 6). The surface protective film PAS can be formed by, for example, a CVD method. The polyimide resin film PI can be formed by, for example, applying polyimide resin onto the surface protective film PAS. Then, an opening penetrating the surface protective film PAS and the polyimide resin film PI to expose the tap pad 1a, the transformer pad 1c, the transformer pad 1e, the tap pad 3a, the transformer pad 3c, and the transformer pad 3d (see FIG. 6) is formed by a photolithography technique and an etching method.

At this time, as illustrated in FIG. 16, the transformer TR made of the upper layer inductor 100 and the lower layer inductor 300 is formed in each of the element regions 1A arranged in the matrix form in the semiconductor wafer WF in plan view. That is, a plurality of patterns (transformers TR) arranged in the matrix form in plan view are formed.

Then, as illustrated in FIG. 17, the semiconductor wafer WF is cut by dicing, thereby separating the plurality of element regions 1A to form the plurality of semiconductor chips CHP3a and the plurality of semiconductor chips CHP3b. After a tape is pasted to cover the back surface of the semiconductor substrate SB, the dicing is performed to cut the multilayer wiring layer ML and the semiconductor substrate SB.

For example, as illustrated in FIG. 17, the dicing is performed in the X-direction from each of an X-axis cutting position X1, an X-axis cutting position X2, and an X-axis cutting position X3, and the dicing is performed in the Y-direction from each of a Y-axis cutting position Y1 to a Y-axis cutting position Y4. Each of all the X-axis cutting positions is a position where a space between the element regions 1A adjacent to each other in the Y-direction is cut, and each of all the Y-axis cutting positions is a position where a space between the element regions 1A adjacent to each other in the X-direction is cut. The Y-axis cutting position Y1 to the Y-axis cutting position Y4 are equally spaced apart from one another in the X-direction, and the number of the element regions 1A arranged in the X-direction between the adjacent Y-axis cutting positions is only one. On the other hand, the X-axis cutting position X1 to the X-axis cutting position X3 do not need not be equally spaced apart from one another. For example, in the Y-direction, the number of the element regions 1A arranged between the X-axis cutting position X1 and the X-axis cutting position X2 that are adjacent to each other is two, while the number of the element regions 1A arranged between the X-axis cutting position X2 and the X-axis cutting position X3 that are adjacent to each other is one.

By the dicing performed as described above, the plurality of semiconductor chips CHP3b each including the two element regions 1A are formed from a region between the X-axis cutting position X1 and the X-axis cutting position X2 that are adjacent to each other. Also, the plurality of semiconductor chips CHP3a each including the one element region 1A are formed from a region between the X-axis cutting position X2 and the X-axis cutting position X3 that are adjacent to each other. The semiconductor chip CHP3b including the two transformers TR can be used for the driving controller having two channels as described with reference to FIG. 3. The semiconductor chip CHP3a including the one transformer TR can be used for the driving controller having one channel as described with reference to FIG. 4. If the X-axis cutting positions that are adjacent to each other in the Y-direction are spaced apart from each other to sandwich the three element regions 1A therebetween, a semiconductor chip including the three transformers TR arranged in the Y-direction can be formed. That is, a transformer chip usable for the driving controller having three channels as described with reference to FIG. 5 is obtained.

Thus, in the first embodiment, when a single semiconductor wafer WF is diced, intervals among adjacent X-axis cutting positions are not equalized, and the dicing is performed with a plurality of types of intervals. In this manner, the plurality of types of semiconductor chips respectively having different numbers of the formed transformers TR can be formed from the single semiconductor wafer WF.

As described above, the semiconductor device according to the first embodiment can be formed. Among the semiconductor chips formed as described above, for example, the semiconductor chip CHP3b including the two transformers TR is arranged between, for example, the semiconductor chip CHP1b and the semiconductor chip CHP2b as illustrated in FIG. 3. FIG. 18 is a schematic view illustrating a semiconductor package using the semiconductor device according to the first embodiment. As illustrated in FIG. 18, a semiconductor chip CHP1b is bonded onto a die DI1, a semiconductor chip CHP2b is bonded onto a die DI2, and a semiconductor chip CHP3b is bonded onto a die DI3.

Then, the tap pad 1a, the transformer pad 1c, and the transfer pad 1e of the semiconductor chip CHP3b (see FIG. 6) are respectively connected to pads of the primary-side semiconductor chip CHP1b, respectively, via bonding wires BW. The tap pad 3a, the transformer pad 3c, and the transformer pad 3d of the semiconductor chip CHP3b (see FIG. 6) are connected to pads of the secondary-side semiconductor chip CHP2b, respectively, via bonding wires BW. Each of the semiconductor chip CHP1b and the semiconductor chip CHP2b is connected to a plurality of lead frames LFs, respectively, via bonding wires. Note that the tap pad 1a and the tap pad 3a do not always need be connected to different semiconductor chips. Then, the semiconductor package can be manufactured by sealing the die DI1, the die DI2, the die DI3, the plurality of lead frames IF, the semiconductor chip CHP1b, the semiconductor chip CHP2b, and the semiconductor chip CHP3b all together with resin mold MD.

### Effects of First Embodiment

As described with reference to FIGS. 3 to 5, in a case of the driving controller 3 made of three chips, it is conceivable that the primary-side semiconductor chip, the transformer chip, and the secondary-side semiconductor chip are designed to respectively be fitted with applications of the driving controller. However, when the semiconductor chips are designed to respectively be fitted with the applications of the driving controller, costs for design man-hours and manufacturing management (control of a production quantity) increase.

For example, when the transformer chip is cut from an 8-inch semiconductor wafer, about 22,000 transformer chips having one channel can be formed from one semiconductor wafer. Similarly, about 14,000 transformer chips having two channels can be formed from one semiconductor wafer, and about 10,000 transformer chips having three channels can be formed from one semiconductor wafer. Since transformer chips more than necessary are formed for each of products respectively having different numbers of channels, there are problems that are not only the increase in the manufacturing cost of the transformer chip but also poor production efficiency. Particularly, advancement of element miniaturization increases the number of semiconductor chips formed from one semiconductor wafer, and therefore, the production efficiency is further reduced.

In the first embodiment, as illustrated in FIG. 17, the transformers TR with the same layout are respectively formed in the element regions 1A arranged in the matrix form in the semiconductor wafer WF. Therefore, the design of the semiconductor chip does not need to be changed for each of the transformer chips respectively having different numbers of channels, and therefore, the design cost of the transformer chip can be reduced.

By appropriate change in the cutting size of the semiconductor chip in the dicing step, the transformer chips respectively having the plurality of types of channels can be formed from one semiconductor wafer WF. That is, the arrangement of the plurality of Y-axis cutting positions is set at a constant interval, while the interval between the adjacent X-axis cutting positions is not constant but appropriately changed. In this manner, the number of channels (the number of transformers to be mounted) of the semiconductor chip to be cut out of the semiconductor wafer WF can changed. Therefore, only the necessary number of semiconductor chips respectively having different numbers of channels can be formed from one semiconductor wafer WF, thereby suppressing the formation of excess chips. From the above, the manufacturing cost of the semiconductor device can be reduced.

As illustrated in FIGS. 3 and 18, the semiconductor chip CHP3b is arranged between the primary-side semiconductor chip CHP1b and the secondary-side semiconductor chip CHP2b. The semiconductor chip CHP3b is connected to each of the semiconductor chip CHP1b and the semiconductor chip CHP2b via the bonding wires BW. Accordingly, it is desirable that the plurality of transformers configuring the transformer chip are arranged in a direction perpendicular to the arrangement direction of the semiconductor chip CHP1b, the semiconductor chip CHP3b, and the semiconductor chip CHP2b in plan view. The same applies to a case where the number of transformers formed in the transformer chip is three or more.

For example, as illustrated in FIG. 34 as a first comparative example, a case of a transformer chip including a total of four transformers TR in which two transformers in the X-direction and two transformers in the Y-direction are arranged in plan view is conceivable. In this case, even if it is attempted to connect the transformer chip and another semiconductor chip to each other via bonding wires, the bonding wires cannot be formed because the plurality of bonding wires overlap one another. As illustrated in FIG. 35 as a second comparative example, even in a case of a transformer chip including transformers TR with a staggered form, the bonding wires cannot be formed, either.

In the first embodiment, as illustrated in FIG. 17, every one of the Y-axis cutting positions Y1 to Y4 is arranged for each of boundaries among the element regions 1A arranged in the X-direction. In this manner, each of both ends of each element direction. region 1A in the X-direction is always cut by the dicing step. Accordingly, the number of transformers arranged in the X-direction (the respective numbers of upper layer inductors and lower layer inductors) in the cut-out semiconductor chip is one. Therefore, in the transformer chip, the transformers are arranged side by side only in the Y-direction, and therefore, the transformer chip is easily bonded to the primary-side semiconductor chip and the secondary-side semiconductor chip.

### Modification Example

In the first embodiment described with reference to FIGS. 1 to 18, the formation of the plurality of types of transformer chips from one semiconductor wafer has been described. In a modification example of the first embodiment, formation of different types of transformer chips for each semiconductor wafer will be described with reference to FIGS. 19 and 20.

FIG. 19 is a perspective view illustrating a lot including a plurality of semiconductor wafers according to the modification example of the first embodiment. The lot is a designation (name) used as a unit in production of the semiconductor device. One lot includes, for example, about 25 semiconductor wafers. FIG. 20 is a plan view in a step of manufacturing a semiconductor device according to the modification example of the first embodiment.

In the step of manufacturing the semiconductor device, one lot LT is first prepared. The one lot LT includes a plurality of semiconductor wafers WF housed in a box BX.

Then, one semiconductor wafer WF is extracted from the lot LT, thereby preparing the semiconductor substrate SB as described with reference to FIG. 8. Then, the plurality of transformers TR are formed on the semiconductor wafer WF by performing the steps described with reference to FIGS. 9 to 16.

Then, as illustrated on the left side of FIG. 20, the semiconductor wafer WF is cut by the dicing, thereby separating the plurality of element regions 1A to form the plurality of semiconductor chips CHP3a. From the semiconductor wafer WF, only a plurality of semiconductor chip CHP3a each including one transformer TR are cut out, while a semiconductor chip including two or more transformers TR is not cut out, as different from the step described in FIG. 17.

Then, one semiconductor wafer WF is extracted from the lot LT, thereby preparing the semiconductor substrate SB as described with reference to FIG. 8. Then, the plurality of transformers TR are formed on the semiconductor wafer WF by performing the steps described with reference to FIGS. 9 to 16.

Then, as illustrated on the right side of FIG. 20, the semiconductor wafer WF is cut by the dicing, thereby separating the plurality of element regions 1A to form the plurality of semiconductor chips CHP3b. From the semiconductor wafer WF, only the plurality of semiconductor chips CHP3b each including two transformers TR are cut out, while a semiconductor chip including one, three or more transformers TR is not cut out, as different from the step described in FIG. 17.

As described above, the semiconductor device according to the modification example of the first embodiment can be formed. The plurality of element regions 1A are formed by the same step in each of the plurality of semiconductor wafer WFs included in the lot LT. The X-axis cutting position is changed for each of the semiconductor wafers WF, thereby performing the dicing at a different portion. In this manner, the different type of semiconductor chip can be formed for each semiconductor wafer WF. That is, for example, the plurality of semiconductor chips CHP3a each including one transformer TR can be formed from one semiconductor wafer WF while the plurality of semiconductor chips CHP3b each including two transformers TR can be formed from another one semiconductor wafer WF.

Therefore, the different types of semiconductor chips can be formed from the plurality of semiconductor wafers each including elements formed by the same step. The design does not need to be changed for each of the plurality of semiconductor wafers in order to form the transformer chips respectively having different numbers of channels from the plurality of semiconductor wafers, and therefore, the design cost of the transformer chip can be reduced.

### Second Embodiment

The following is explanation about half-cutting of a semiconductor substrate to be performed as a structure for preventing the propagation of crosstalk noise between the adjacent transformers in the transformer chip.

### Structure of Semiconductor Device

FIG. 21 illustrates a planar layout of a semiconductor chip as a semiconductor device according to a second embodiment. FIG. 22 is a cross-sectional view of the semiconductor chip taken along a line B-B illustrated in FIG. 21.

A semiconductor chip CHP3b illustrated in FIGS. 21 and 22 differs from that in the first embodiment in that the main surface (upper surface) of the semiconductor substrate SB is cut down to a middle depth of the semiconductor substrate SB at a boundary between the adjacent element regions 1A so as to separate structures including the multilayer wiring layer ML, the surface protective film PAS, and the polyimide resin film PI on the semiconductor substrate SB. The other structures of the semiconductor chip CHP3b in the second embodiment are substantially the same as those in the first embodiment illustrated in FIG. 6.

A trench D1 having a predetermined depth from the main surface of the semiconductor substrate SB is formed in the vicinity of the boundary between the adjacent element regions 1A. The trench D1 is arranged between the adjacent transformers TR in plan view. The trench D1 extends from one end of the semiconductor substrate SB to the other end thereof in the X-direction. A depth L1 of the trench D1 is, for example, equal to or larger than 1.75 μm. A thickness of the semiconductor substrate SB is, for example, 250 μm. A region directly over the trench D1 is opened, so that the multilayer wiring layer ML, the surface protective film PAS, the polyimide resin film PI, and other conductor patterns are not formed. Regions inside and directly over the trench D1 are filled with the resin mold MD illustrated in FIG. 18.

### Method of Manufacturing Semiconductor Device

FIG. 23 is a plan view in a step of manufacturing the semiconductor device according to the second embodiment. This is a plan view illustrating a part of the semiconductor wafer WF in the dicing step corresponding to FIG. 17 formed after the steps described with reference to FIGS. 8 to 16. In the dicing step in the second embodiment, a structure (a multilayer wiring layer ML, etc.) on the semiconductor substrate SB is cut, and the half-cutting is performed to form the trench D1 (see FIG. 22) extending from the main surface of the semiconductor substrate SB down to the middle depth. The half-cutting is performed at an X-axis portion removal position XA illustrated in FIG. 23. In the half-cutting, the semiconductor substrate SB does not need to be cut down to half of the thickness of the semiconductor substrate SB, and a depth of the trench D1 may be, for example, equal to or larger than 1.75 μm. The half-cutting is performed using, for example, a dicing blade. However, the trench D1 may be formed on the main surface of the semiconductor substrate SB by not using the dicing blade but performing laser grooving, thereby removing the structure (multilayer wiring layer ML, etc.) on the semiconductor substrate SB.

Then, as similar to the first embodiment, the semiconductor wafer WF is cut using the dicing blade at the X-axis cutting position X1, the X-axis cutting position X2, the Y-axis cutting position Y1, the Y-axis cutting position Y2, and the Y-axis cutting position Y3. In this manner, the plurality of types of semiconductor chips respectively including the different numbers of transformers TR can be formed from the semiconductor wafer WF.

The half-cutting in the second embodiment is not performed to the semiconductor chip including one transformer. The X-axis portion removal position is set to a position not overlapping the X-axis cutting position. In the semiconductor chip including two or more transformers formed therein, the half-cutting is performed to a region between the adjacent transformers. That is, the half-cutting is performed in the X-direction to all boundaries among the element regions 1A in the region between the X-axis cutting positions adjacent to each other in the Y-direction. In FIG. 23, in the Y-direction, the X-axis cutting position and the X-axis portion removal position are alternately set as the cut portion for the semiconductor chip including two transformers. Also, as a part of the cut portion for the semiconductor chip including three or more transformers, the X-axis portion removal positions are set to be adjacent to each other to sandwich one element region 1A therebetween.

### Effects of Second Embodiment

In the transformer chip including the plurality of transformers, there is a risk of propagation of the crosstalk noise between the adjacent transformers via the semiconductor substrate. The propagation of the crosstalk noise is capacitive noise propagation caused by a capacitance between the semiconductor substrate and a wiring (lower layer wiring) in a lowermost layer of the multilayer wiring layer. That is, in each channel (each transformer), a capacitance is generated between the semiconductor substrate and the lower layer wiring. The crosstalk noise propagates from one transformer to the other transformer after sequentially passing through a capacitance of the one transformer, the semiconductor substrate, a and capacitance of the other transformer.

Therefore, it is conceivable that, if the first layer wiring M1 illustrated in FIG. 13 is not formed, the capacitance between the semiconductor substrate SB and the lower layer wiring is reduced, thereby suppressing occurrence of the crosstalk noise. That is, if the first layer wiring M1 is not formed, a distance between the semiconductor substrate SB and the lower layer wiring becomes larger than that in the case with the wiring M1, and therefore, the capacitance is reduced.

In order to reduce the crosstalk noise, it is conceivable that the wiring M1 is formed to insulate the wiring M1 from the lower layer inductor 300 and cover the entire main surface of the semiconductor substrate SB. However, in this method, the wiring M1 needs to be cut in the dicing step. In this case, the aluminum configuring the wiring M1 adheres to the dicing blade, and the dicing blade needs to be frequently washed or replaced. Therefore, the productivity of the semiconductor device is reduced. Also, it is conceivable that the above-described capacitance is reduced by further forming an oxide film between the semiconductor substrate SB and the lower layer wiring. However, in this case, the semiconductor chip easily bends.

In the second embodiment, since the trench D1 is formed in the main surface of the semiconductor substrate SB, the propagation of the crosstalk noise can be prevented even without the removal of the wiring M1, the formation of the wiring M1 on the entire surface, or the formation of the oxide film as described above. That is, the crosstalk noise propagates from the main surface of the semiconductor substrate through a relatively shallow region, while the propagation of the crosstalk noise can be interrupted because of the formation of the trench D1. Therefore, the performance of the semiconductor device can be improved.

The capacitance is desirably reduced by grooving the semiconductor substrate SB to correspond to an amount of the capacitance reduction due to the thickness of the insulating film between a bottom surface of the wiring M1 and a second layer wiring on the wiring M1 in the case of suppressing the occurrence of the crosstalk noise by not forming the first layer wiring M1. The present inventors have taken into consideration a difference in dielectric constant between silicon oxide configuring the insulating film and silicon (Si) configuring the semiconductor substrate SB, and have converted the amount of the capacitance reduction due to the thickness of the insulating film into an amount of capacitance reduction due to the grooving of the semiconductor substrate SB. As a result, the inventors have found that the propagation of the crosstalk noise can be effectively prevented when the amount of the grooving of the semiconductor substrate SB is equal to or larger than 1.75 μm. Accordingly, in the second embodiment, the depth of the trench D1 is set to be equal to or larger than 1.75 μm.

### Modification Example

In FIG. 23, the case where the X-axis cutting position and the X-axis portion removal position are alternately set so that the X-axis cutting position and the X-axis portion removal position do not overlap each other has been described. On the other hand, the X-axis portion removal position and the X-axis cutting position may overlap each other. In other words, the region where the semiconductor wafer WF is cut may overlap a part of the trench D1 formed by the half-cutting in plan view. That is, so-called step dicing may be performed, the step dicing being a process of performing the half-cutting at the X-axis portion removal position and then cutting the half-cut region by using the dicing blade.

In the case, it is conceivable that, for example, all boundaries among the element regions 1A adjacent to each other in the Y-direction are half-cut, respectively, as the X-axis cutting positions. On the other hand, the X-axis cutting positions are set depending on the necessary type of the transformer chip as similar to the first embodiment.

In the step dicing, first, for example, as illustrated in FIG. 24, the main surface of the semiconductor substrate SB is irradiated with a laser LD. In this manner, the laser grooving is performed, thereby removing the structure (the multilayer wiring layer ML, etc.) on the semiconductor substrate SB, and forming the trench D1 in the main surface of the semiconductor substrate SB. In this case, the tape TP is pasted onto the entire back surface of the semiconductor substrate SB before the half-cutting (laser grooving) is performed.

Then, as illustrated in FIG. 25, the semiconductor substrate SB is cut using the dicing blade DB to cut a region from a bottom surface of the trench D1 to a bottom surface of the semiconductor substrate SB. A width of the dicing blade DB is smaller than a width of the trench D1. The step dicing is performed as described above, thereby suppressing formation of a residue due to the dicing. Also, this prevents cracking or chipping of the semiconductor chip due to the dicing.

The half-cutting performed using the laser grooving has been described here. However, the half-cutting may be performed using a dicing blade DBA as illustrated in FIG. 26. Alternatively, the half-cutting may be performed using a dicing blade DBB as illustrated in FIG. 27. A cross-sectional shape of a tip of the dicing blade DBB is a V shape. A width of the dicing blade DB to be used for the subsequent cutting step is smaller than widths of both the dicing blade DBA and the dicing blade DBB. This case uses the dicing blade DBA or the dicing blade DBB suitable for the cutting of the multilayer wiring layer ML and the dicing blade DB suitable for the cutting of the semiconductor substrates SB, and therefore, a high-quality processing result is obtained. When the V-shaped dicing blade DBB as illustrated in FIG. 27 is used, chamfering processing is performed during the cutting, and therefore, high-quality cutting with a high bending strength is achieved.

### Third Embodiment

In a third embodiment, formation of an n-type semiconductor region instead of the p-type semiconductor region PR illustrated in FIG. 7 as the method of reducing the crosstalk noise will be described.

FIG. 28 is a cross-sectional view of a semiconductor device according to the third embodiment. FIG. 28 illustrates a mode in which two transformers TR are arranged in one transformer chip. In FIG. 28, illustrations of the conductor other than the conductor pattern configuring the transformer TR and the surface protective film PAS, the polyimide resin film PI, and the like on the multilayer wiring layer ML are omitted. A structure of the semiconductor device according to the third embodiment is the same as the structure of the semiconductor device illustrated in FIG. 7 except that an n-type semiconductor region NR1 is formed instead of the p-type semiconductor region PR. The n-type semiconductor region NR1 has a predetermined depth from the main surface of the p-type semiconductor substrate SB. That is, the semiconductor substrate SB includes a p-type semiconductor region and the n-type semiconductor region NR1 formed on the p-type semiconductor region.

The n-type semiconductor region NR1 is connected to a fixed potential (such as a ground potential). The upper layer inductor 100 and the lower layer inductor 300 overlap the n-type semiconductor region NR1 in plan view. The n-type semiconductor region NR1 can be formed in the step described with reference to FIG. 10 by, for example, an ion implantation method of implanting n-type impurities into the main surface of the semiconductor substrate SB. An impurity concentration of the n-type semiconductor region NR1 is, for example, 1×10¹⁹ cm⁻³. A depth of the n-type semiconductor region NR1 from the main surface of the semiconductor substrate SB is, for example, equal to or larger than 0.5 μm and equal to or smaller than 2 μm.

FIG. 36 is a cross-sectional view of a semiconductor device in a third comparative example. A structure illustrated in FIG. 36 differs from that of the semiconductor device according to the third embodiment in that a p-type semiconductor region PR is formed instead of the n-type semiconductor region NR1. In the semiconductor device in the third comparative example, capacitance C1 is formed between the p-type semiconductor region PR formed in the semiconductor substrate SB and arranged on the main surface of the semiconductor substrate SB and a wiring M1 as a lower layer wiring directly over the p-type semiconductor region PR. The larger the capacitance between the lower layer wiring and the semiconductor substrate SB is, the more noticeable the occurrence of the crosstalk noise (capacitive noise) between the lower layer wiring and the semiconductor substrate SB is.

Accordingly, in the third embodiment, the n-type semiconductor region NR1 is formed on the main surface of the semiconductor substrate SB. In each of the transformers TR, a capacitance C2 is formed between the n-type semiconductor region NR1 and the wiring M1, and a capacitance C3 is formed between the n-type semiconductor region NR1 and the p-type semiconductor substrate SB. The capacitance C2 and the capacitance C3 are connected in series between the wiring M1 and the semiconductor substrate SB. A reciprocal of a composite capacitance between the wiring M1 and the semiconductor substrate SB is the sum of the respective reciprocals of the capacitance C2 and the capacitance C3. That is, the composite capacitance between the wiring M1 and the semiconductor substrate SB is smaller than all respective values of the capacitance C1, the capacitance C2, and the capacitance C3. Therefore, in the third embodiment, since the capacitance C3 is formed between the n-type semiconductor region NR1 and the semiconductor substrate SB, the propagation of the crosstalk noise is more suppressed than that in the third comparative example illustrated in FIG. 36.

### Modification Example

As illustrated in FIG. 29, in a portion where the n-type semiconductor region NR1 illustrated in FIG. 28 is formed, an n-type semiconductor region having a NR2 lower impurity concentration than that of the n-type semiconductor region NR1 may be formed directly below the transformer TR. FIG. 29 is a cross-sectional view illustrating a semiconductor device according to a modification example of the third embodiment.

FIG. 29 illustrates a mode in which two transformers TR are arranged in one transformer chip. The n-type semiconductor region NR1 and the n-type semiconductor region NR2 are formed inside the p-type semiconductor substrate SB. Each of the n-type semiconductor region NR1 and the n-type semiconductor region NR2 is formed to have a predetermined depth from the main surface of the p-type semiconductor substrate SB. An impurity concentration of the n-type semiconductor region NR1 is higher than an impurity concentration of the n-type semiconductor region NR2. That is, in comparison between the impurity concentration of the n-type semiconductor region NR1 and the impurity concentration of the n-type semiconductor region NR2, the n-type semiconductor region NR1 is a high concentration region while the n-type semiconductor region NR2 is a low concentration region. The n-type semiconductor region NR2 is formed at a position overlapping the lower layer inductor 300 and the upper layer inductor 100 in plan view. The n-type semiconductor region NR1 is formed at a position spaced apart from the lower layer inductor 300 and the upper layer inductor 100 in plan view. The n-type semiconductor region NR1 and the n-type semiconductor region NR2 are in contact with each other in the X-direction or the Y-direction. That is, the n-type semiconductor region NR1 and the n-type semiconductor region NR2 are electrically connected to each other. The n-type semiconductor region NR1 is connected to a fixed potential (such as a ground potential).

The n-type semiconductor region NR1 and the n-type semiconductor region NR2 can be formed in the step described with reference to FIG. 10 by, for example, an ion implantation method of implanting n-type impurities into the main surface of the semiconductor substrate SB. For example, the n-type For semiconductor region NR1 is formed on the main surface of the semiconductor substrate SB, and then, the n-type semiconductor region NR2 is formed by performing ion implantation using a resist pattern as a mask. An impurity concentration of the n-type semiconductor region NR1 is, for example, 1×10¹⁹ cm⁻³, and an impurity concentration of the n-type semiconductor region NR2 is, for example, 1×10¹⁷ cm⁻³. Each depth of the n-type semiconductor region NR1 and the n-type semiconductor region NR2 from the main surface of the semiconductor substrate SB is, for example, equal to or larger than 0.5 μm and equal to or smaller than 2 μm. In each of the transformers TR, a capacitance C4 is formed between the n-type semiconductor region NR2 and the wiring M1, and a capacitance C5 is formed between the n-type semiconductor region NR2 and the p-type semiconductor substrate SB.

In this modification example, the impurity concentration of the n-type semiconductor region NR2 directly below the transformer TR is lower than the impurity concentration of the n-type semiconductor region NR1 in the semiconductor device described with reference to FIG. 28. Accordingly, a capacitance component (the capacitance C5) of bonding between the n-type semiconductor region NR2 and the semiconductor substrate SB is smaller than a capacitance component (the capacitance C3) of bonding between the n-type semiconductor region NR1 and the semiconductor substrate SB illustrated in FIG. 28. This is because a depletion layer expands from a bonding surface between the n-type semiconductor region NR2 and the semiconductor substrate SB toward an upper surface of the n-type semiconductor region NR2 so as to reduce the capacitance C5.

Therefore, in this modification example, since the value of the capacitance C5 between the n-type semiconductor region NR2 and the semiconductor substrate SB is reduced, the propagation of the crosstalk noise is more suppressed than that in the semiconductor device illustrated in FIG. 28.

### Fourth Embodiment

The following is explanation about formation of an element isolation region in the semiconductor substrate as a method of preventing the propagation of the crosstalk noise between the adjacent transformers in the transformer chip.

### Structure of Semiconductor Device

FIG. 30 illustrates a planar layout of a semiconductor chip as a semiconductor device according to a fourth embodiment. FIG. 31 is a cross-sectional view of the semiconductor chip taken along a line C-C illustrated in FIG. 30.

A semiconductor chip CHP3b illustrated in FIGS. 30 and 31 differs from that in the first embodiment in that an element isolation region DTI is formed in a trench D2 that is formed on the main surface (upper surface) of the semiconductor substrate SB at the boundary between the adjacent element regions 1A. The other structure of the semiconductor chip CHP3b according to the fourth embodiment is substantially the same as the structure of the semiconductor chip according to the first embodiment illustrated in FIG. 6.

On the main surface of the semiconductor substrate SB, the trench D2 extending to a middle depth of the semiconductor substrate SB is formed in the vicinity of the boundary of the adjacent element regions 1A. That is, the trench D2 having a predetermined depth from the main surface of the semiconductor substrate SB is formed. The trench D2 is arranged between the adjacent transformers TR in plan view. A depth L2 of the trench D2 is, for example, equal to or larger than 1.75 μm. In the trench D2, the element isolation region DTI mainly made of silicon oxide is formed. The element isolation region DTI is made of the insulating film configuring the multilayer wiring layer ML. An upper part of the element isolation region DTI is covered with the insulating film configuring the multilayer wiring layer ML, the surface protective film PAS, and the polyimide resin film PI.

### Method of Manufacturing Semiconductor Device

FIG. 32 is a cross-sectional view in a step of manufacturing the semiconductor device according to the fourth embodiment. FIG. 32 is a cross-sectional view illustrating a state after the formation of the p-type semiconductor region PR in the semiconductor substrate SB as described with reference to FIGS. 8 to 10 and before the step described with reference to FIG. 11.

First, as illustrated in FIG. 32, the trench D2 is formed on the main surface of the semiconductor substrate SB. For example, a hard mask made of an insulating film is formed on the main surface of the semiconductor substrate SB, and then, the hard mask is patterned by a photolithography technique and an etching method. In this patterning, an opening that penetrates the hard mask is formed to expose a part of the main surface of the semiconductor substrate SB positioned at the boundary between the element regions 1A adjacent to each other in the Y-direction. Then, dry etching is performed using the hard mask as an etching prevention mask, thereby forming the trench D2 on the main surface of the semiconductor substrate SB below the opening. Then, the hard mask is removed by, for example, a wet etching method.

Then, as described with reference to FIG. 11, an insulating film IF1 is formed on the main surface of the semiconductor substrate SB. In this manner, the trench D2 is filled with the insulating film IF1. The insulating film IF1 left in the trench D2 configures the element isolation region DTI.

Then, the step of forming the conductive connection section CP described with reference to FIG. 11 and the steps described with reference to FIGS. 12 to 16 are performed, thereby forming a structure illustrated in FIGS. 33 and 31. The element isolation region DTI positioned at the boundary between the element regions 1A adjacent to each other in the Y-direction is covered with the insulating film configuring the multilayer wiring layer ML. However, a conductor pattern is not formed directly over the element isolation region DTI.

As illustrated in FIG. 33, the element isolation region DTI is positioned between the transformers TR adjacent to each other in the Y-direction in plan view. The element isolation region DTI extends in the X-direction. The element isolation region DTI is not formed in the vicinity of the boundary between the element regions 1A adjacent to each other in the X-direction. That is, the element isolation regions DTI adjacent to each other in the Y-direction are separated from each other. Accordingly, the element isolation region DTI is spaced apart from the Y-axis cutting position in plan view.

In the dicing step described with reference to FIG. 17, the dicing is performed to, for example, the same portion as that in the first embodiment to separate the semiconductor wafer WF. At this time, at the X-axis cutting position, the element isolation region DTI is also cut together with the semiconductor substrate SB and the multilayer wiring layer ML. A Y-direction width of the element isolation region DTI can be either smaller or larger than a Y-direction width of the dicing blade that performs the cutting at the X-axis cutting position.

At the boundary between the element regions 1A adjacent to each other in the Y-direction as well as a portion where the dicing in the X-direction is not performed, the element isolation region DTI is left as a part of the semiconductor chip. That is, in the transformer chip including the plurality of transformers TR arranged in the Y-direction, the element isolation region DTI is left inside the semiconductor substrate SB between the adjacent transformers TR.

As described above, the semiconductor device according to the fourth embodiment can be formed. Note that the trench D2 and the element isolation region DTI may be formed after the step described with reference to FIG. 10 and before the step described with reference to FIG. 11.

### Effects of Fourth Embodiment

In the fourth embodiment, in the transformer chip including the plurality of transformers TR, the element isolation region DTI is formed on the main surface of the semiconductor substrate SB between the adjacent transformers TR. In this manner, the propagation of the crosstalk noise between the adjacent transformers TR can be prevented. This effect is effectively obtained when the depth of the trench D2 is set to be equal to or larger than 1.75 μm as similar to the second embodiment.

In the foregoing, the invention made by the inventors of the present application has been concretely described based on the embodiments. However, it is needless to say that the present invention is not limited to the foregoing embodiments, and various modifications can be made within the scope of the present invention.

For example, the transformer chip described in each of the embodiments may include the capacitor instead of the transformer as elements that transmit and receive signals while keeping insulation between the primary and secondary sides. In the case, instead of the upper layer inductor and the lower layer inductor, a flat plate made of a conductor pattern extending in the X-direction and the Y-direction in plan view is formed. The capacitor is made of an upper flat plate and a lower flat plate that overlap each other in plan view and are capacitively coupled to each other, and does not include a spiral wiring. In the planar layout illustrated in FIG. 6, in the element region 1A, a capacitor used for transmitting a signal of one channel is formed to be surrounded by the conductor pattern W1 and the conductor pattern W2 in plan view.

Also, the semiconductor device according to the third embodiment described with reference to FIGS. 28 and 29 may be combined with the semiconductor device according to the second embodiment or the fourth embodiment. That is, a part of the semiconductor substrate SB in a portion where the n-type semiconductor region NR1 or the n-type semiconductor region NR2 is formed may be removed by performing the half-cutting or forming the element isolation region DTI. At this time, the depth of the trench D1 or the trench D2 can be either larger or smaller than the depth of the n-type semiconductor region NR1 or the n-type semiconductor region NR2.

What is claimed is:

1. A semiconductor device comprising:
a semiconductor substrate including a first semiconductor region of a first conductivity type and a second semiconductor region of a second conductivity type different from the first conductivity type, arranged on the first semiconductor region;
a first pattern overlapping the second semiconductor region in plan view and formed over the semiconductor substrate; and
a second pattern overlapping the first pattern in plan view, and magnetically or capacitively coupled to the first pattern.

2. The semiconductor device according to claim 1, further comprising:
a third pattern overlapping the second semiconductor region in plan view and formed over the semiconductor substrate; and
a fourth pattern overlapping the third pattern in plan view and magnetically or capacitively coupled to the third pattern.

3. The semiconductor device according to claim 2,
wherein the first pattern is a first inductor,
wherein the second pattern is a second inductor,
wherein the third pattern is a third inductor,
wherein the fourth pattern is a fourth inductor,
wherein the first inductor and the second inductor are magnetically coupled to each other, and
wherein the third inductor and the fourth inductor are magnetically coupled to each other.

4. The semiconductor device according to claim 2,
wherein the first pattern is a first flat plate,
wherein the second pattern is a second flat plate,
wherein the third pattern is a third flat plate,
wherein the fourth pattern is a fourth flat plate,
wherein the first flat plate and the second flat plate are capacitively coupled to each other, and
wherein the third flat plate and the fourth flat plate are capacitively coupled to each other.

5. The semiconductor device according to claim 2, further comprising:
a first conductor pattern surrounding the first pattern and the second pattern in plan view; and
a second conductor pattern surrounding the third pattern and the fourth pattern in plan view,
wherein the first conductor pattern and the second conductor pattern are spaced apart from each other.

6. The semiconductor device according to claim 2,
wherein the second semiconductor region includes:
a low concentration region; and
a high concentration region having a higher impurity concentration than an impurity concentration of the low concentration region,
wherein the first pattern and the third pattern overlap the low concentration region in plan view, and
wherein the high concentration region is connected to a fixed potential.

7. The semiconductor device according to claim 2, further comprising:
a trench formed in the semiconductor substrate, the trench having a predetermined depth from a main surface of the semiconductor substrate, and the trench being arranged between the first pattern and the third pattern in plan view.

8. The semiconductor device according to claim 7,
wherein the first pattern and the third pattern are arranged in a first direction, and
wherein the trench extends from one end of the semiconductor substrate to the other end of the semiconductor substrate in a second direction perpendicular to the first direction in plan view.

9. The semiconductor device according to claim 2, further comprising:
a first circuit driven at a first voltage; and
a second circuit driven at a second voltage different from the first voltage,
wherein the first pattern is electrically connected to the first circuit, and
wherein the third pattern is electrically connected to the second circuit.

10. A method of manufacturing a semiconductor device, the method comprising:
(a) preparing a lot including a plurality of semiconductor wafers;
(b) forming a plurality of patterns arranged in a matrix form in plan view over each of the plurality of semiconductor wafers;
(c) cutting a first semiconductor wafer among the plurality of semiconductor wafers in a first direction along a main surface of the first semiconductor wafer to form a first semiconductor chip having n (n is a positive natural number) first patters among the plurality of patterns arranged in a second direction perpendicular to the first direction; and
(d) cutting a second semiconductor wafer different from the first semiconductor wafer among the plurality of semiconductor wafers in a third direction along a main surface of the second semiconductor wafer to form a second semiconductor chip having m (m is a positive natural number different from n) second patters among the plurality of patterns arranged in a fourth direction perpendicular to the third direction,
wherein each of the plurality of patterns includes:
a lower pattern;
an upper pattern overlapping the lower pattern in plan view and magnetically or capacitively coupled to the lower pattern; and
a conductor pattern surrounding the lower pattern and the upper pattern in plan view.

11. A method of manufacturing a semiconductor device, the method comprising:
(a) preparing a semiconductor wafer;
(b) forming a plurality of patterns arranged in a matrix form in plan view over the semiconductor wafer; and
(c) cutting the semiconductor wafer in a first direction along a main surface of the semiconductor wafer to form a first semiconductor chip having n (n is a positive natural number) first patters among the plurality of patterns arranged in a second direction perpendicular to the first direction and a second semiconductor chip having m (m is a positive natural number different from n) second patterns among the plurality of patterns arranged in the second direction,
wherein each of the plurality of patterns includes:
a lower pattern;
an upper pattern overlapping the lower pattern in plan view and magnetically or capacitively coupled to the lower pattern; and
a conductor pattern surrounding the lower pattern and the upper pattern in plan view.

12. The method according to claim 11,
wherein the lower pattern is a first inductor,
wherein the upper pattern is a second inductor, and
wherein the first inductor and the second inductor are magnetically coupled to each other.

13. The method according to claim 11,
wherein the lower pattern is a first flat plate,
wherein the upper pattern is a second flat plate, and
wherein the first flat plate and the second flat plate are capacitively coupled to each other.

14. The method according to claim 11,
wherein the number of the first patterns arranged in the first direction in the first semiconductor chip is one, and
wherein the number of the second patterns arranged in the first direction in the second semiconductor chip is one.

15. The method according to claim 11, further comprising:
(b1) after the (b) and before the (c), forming a trench having a predetermined depth from the main surface of the semiconductor wafer, between two patterns among the plurality of patterns adjacent to each other in the second direction in plan view and at the main surface of the semiconductor wafer,
wherein the first semiconductor chip or the second semiconductor chip has the trench.

16. The method according to claim 15,
wherein a region where the semiconductor wafer is cut in the (c) overlaps a part of the trench in plan view.

17. The method according to claim 15,
wherein a region where the semiconductor wafer is cut in the (c) is spaced apart from the trench in plan view.

18. The method according to claim 11, further comprising:
(a1), before the (b), introducing impurities into the semiconductor wafer including a first semiconductor region of a first conductivity type, to form a second semiconductor region of a second conductivity type different from the first conductivity type in the semiconductor wafer and on the first semiconductor region,
wherein the second semiconductor region is formed at the main surface of the semiconductor wafer, and
wherein in the (b), the plurality of patterns are formed over the semiconductor wafer to overlap the second semiconductor region.

19. The method according to claim 18,
wherein the second semiconductor region includes:
a low concentration region; and
a high concentration region having a higher impurity concentration than an impurity concentration of the low concentration region,
wherein the plurality of patterns overlap the low concentration region in plan view, and
wherein the high concentration region is connected to a fixed potential.

20. The method according to claim 11, further comprising:
(a1), after the (a) and before the (b), forming a trench extending from a main surface of the semiconductor wafer to a middle depth of the semiconductor wafer, at the main surface of the semiconductor wafer;
(a2) filling the trench with an insulating material to form an element isolation region in the semiconductor wafer; and
(d) cutting the semiconductor wafer in the second direction,
wherein the element isolation region is positioned between two patterns among the plurality of patterns adjacent to each other in the second direction in plan view, and
wherein in the (d), the semiconductor wafer is cut so as not to cut the element isolation region.

21. The method according to claim 12,
wherein the lower pattern included in each of the plurality of patterns is electrically connected to a first circuit driven at a first voltage, and
wherein the upper pattern included in each of the plurality of patterns is electrically connected to a second circuit driven at a second voltage different from the first voltage.
